(19) United States
(12) Patent Application Publication
(10) Pub. No.: US 2026/0150467 A1
(43) Pub. Date: May 28, 2026

(54) DISPLAY DEVICE AND METHOD OF MANUFACTURING THE SAME

(71) Applicant: LG Display Co., Ltd., Seoul (KR)

(72) Inventors: Su-Min LEE, Paju-si (KR); Kwang-Su LIM, Paju-si (KR); So-Young LEE, Paju-si (KR); So-Yi LEE, Paju-si (KR); Young-In JANG, Paju-si (KR)

(73) Assignee: LG Display Co., Ltd., Seoul (KR)

(21) Appl. No.: 19/324,774

(22) Filed: Sep. 10, 2025

(30) Foreign Application Priority Data
Nov. 22, 2024 (KR) 10-2024-0168020

(51) Int. Cl. H10H 29/80; H10H 29/01; H10H 29/02; H10H 29/41; H10H 29/49

(52) U.S. Cl. CPC H10H 29/842; H10H 29/02; H10H 29/034; H10H 29/41; H10H 29/49; H10H 29/8325

(57) ABSTRACT

A display device including a substrate having a display area and a non-display area; a thin film transistor in the display area over the substrate; a first dam at least partially overlapping the thin film transistor; an adhesive layer inside the first dam; a light-emitting element provided on the adhesive layer and including a semiconductor layer, a first element electrode on the semiconductor layer, a second element electrode on the semiconductor layer and disposed higher than the first element electrode, and a protection layer on the first element electrode, the second element electrode, and the semiconductor layer and including a first opening partially exposing a top surface of the first element electrode and a second opening partially exposing a top surface of the second element electrode; and a planarization layer provided over the adhesive layer and surrounding a side surface of the light-emitting element and a side surface of the protection layer. Further, the planarization layer has a hydrophobic property and the protection layer has a hydrophilic property, and the first dam surrounds the light-emitting element with a height of the first element electrode being disposed lower than a height of the first dam, and a height of the second element electrode being disposed higher than the height of the first dam.

### CROSS-REFERENCE TO RELATED APPLICATION

The present application claims priority to Korean Patent Application No. 10-2024-0168020, filed in the Republic of Korea on Nov. 22, 2024, the entire contents of which are hereby expressly incorporated by reference into the present application.

### BACKGROUND

### Technical Field

The present disclosure relates to a display device, and more particularly, to a display device including a light-emitting element and a method of manufacturing the same.

### Discussion of the Related Art

As the information society progresses, a demand for different types of display devices increases, and flat panel display devices (FPD) such as liquid crystal display devices and light-emitting diode display devices have been developed and applied to various fields. Among the flat panel display devices, light-emitting diode display devices emit light due to the radiative recombination of an exciton. The exciton is formed from an electron and a hole by injecting charges into a light-emitting layer between a cathode for injecting electrons and an anode for injecting holes in a light-emitting diode.

Also, the light-emitting diode display device can offer various advantages and improved properties. For instance, compared to the liquid crystal display device, because it is self-luminous, the light-emitting diode display device has a wide viewing angle, and because a backlight unit is not required, the light-emitting diode display device has an ultra-thin thickness and light weight. In addition, the light-emitting diode display device is also advantageous in power consumption.

Further, the light-emitting diode display device may include inorganic-based light-emitting elements and organic-based light-emitting elements. The inorganic-based light-emitting elements have relatively excellent stability, fast response characteristics, and high contrast ratios, and micro light-emitting diodes (micro LEDs or uLED) are widely used as the inorganic-based light-emitting elements for high resolution.

The inorganic-based light-emitting elements can also be formed on a separate growth substrate and transferred to an array substrate of a display device. Then, signal electrodes for transmitting signals to the light-emitting elements are formed on the array substrate of the display device. However, because a pitch of the light-emitting elements on the growth substrate is different from a pitch of the light-emitting elements on the array substrate, in order to transfer the light-emitting elements from the growth substrate to the array substrate, complex transfer steps may be required. During the transfer steps, the light-emitting elements may be transferred to undesirable locations, and thus, the light-emitting elements may not be connected to the electrodes or an electrical short-circuiting may occur between the electrodes.

### SUMMARY

Accordingly, embodiments of the present disclosure are directed to a display device and a method of manufacturing the same that substantially obviate one or more of the problems due to limitations and disadvantages of the related art.

An aspect of the present disclosure is to provide a display device capable of specifying a location of a light-emitting element and a method of manufacturing the same.

Additional features and aspects will be set forth in the description that follows, and in part will be apparent from the description, or can be learned by practice of the inventive concepts provided herein. Other features and aspects of the inventive concepts can be realized and attained by the structure particularly pointed out in the written description, or derivable therefrom, and the claims hereof as well as the appended drawings.

To achieve these and other aspects of the inventive concepts, as embodied and broadly described herein, a display device includes a substrate on which a display area and a non-display area are defined; a thin film transistor in the display area over the substrate; a first dam over the thin film transistor; an adhesive layer inside the first dam; a light-emitting element provided on the adhesive layer and including a first element electrode, a second element electrode, and a protection layer; and a planarization layer provided over the adhesive layer and surrounding a side surface of the light-emitting element, wherein the planarization layer has a different property from the protection layer with respect to water molecules.

In another aspect, a method of manufacturing a display device includes providing a substrate on which a display area and a non-display area are defined; forming a thin film transistor in the display area over the substrate; forming a first dam over the thin film transistor; forming an adhesive layer inside the first dam; transferring a light-emitting element on the adhesive layer, the light-emitting element including a first element electrode, a second element electrode, and a protection layer; and forming a planarization layer over the adhesive layer, the planarization layer surrounding a side surface of the light-emitting element, wherein the planarization layer has a different property from the protection layer with respect to water molecules.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and which are incorporated in and constitute a part of this application, illustrate embodiments of the disclosure and together with the description serve to explain various principles of the disclosure. In the drawings:

FIG. 1 is a view schematically showing a display device according to an embodiment of the present disclosure;

FIG. 2 is a schematic plan view of a sub-pixel of a display device according to an embodiment of the present disclosure;

FIG. 3 is a schematic plan view of a power line of a display device according to an embodiment of the present disclosure;

FIG. 4 is a schematic cross-sectional view of a sub-pixel in a display area of a display device according to a first embodiment of the present disclosure;

FIG. 5 is a schematic cross-sectional view of a non-display area of the display device according to the first embodiment of the present disclosure;

FIGS. 6A to 6I are schematic cross-sectional views of a display device corresponding to line I-I′ of FIG. 1 in steps of manufacturing the same according to the first embodiment of the present disclosure;

FIGS. 7A to 7H are schematic cross-sectional views of the display device corresponding to line II-II′ of FIG. 1 in steps of manufacturing the same according to the first embodiment of the present disclosure;

FIG. 8 is a schematic cross-sectional view of a sub-pixel in a display area of a display device according to a second embodiment of the present disclosure;

FIG. 9 is a schematic cross-sectional view of a non-display area of the display device according to the second embodiment of the present disclosure;

FIGS. 10A to 10I are schematic cross-sectional views of a display device corresponding to line I-I′ of FIG. 1 in steps of manufacturing the same according to the second embodiment of the present disclosure; and

FIGS. 11A to 11H are schematic cross-sectional views of the display device corresponding to line II-II′ of FIG. 1 in steps of manufacturing the same according to the second embodiment of the present disclosure.

### DETAILED DESCRIPTION

Advantages and features of the present disclosure and methods for achieving them will be made clear from embodiments described in detail below with reference to the accompanying drawings. The present disclosure can, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto. A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure. The same reference numerals refer to the same components throughout this disclosure.

Further, in the following description of the present disclosure, when a detailed description of a known related art is determined to unnecessarily obscure the gist of the present disclosure, the detailed description thereof will be omitted herein or may be briefly discussed. When terms such as “including,” “having,” “comprising” and the like mentioned in this disclosure are used, other parts can be added unless the term “only” is used herein. Further, when a component is expressed as being singular, being plural is included unless otherwise specified.

In analyzing a component, an error range is interpreted as being included even when there is no explicit description. In describing a positional relationship, for example, when a positional relationship of two parts/layers is described as being “over,” “on,” “above,” “below,” “under,” “next to,” or the like, one or more other parts/layers can be provided between the two parts/layers, unless the term “immediately” or “directly” is used therewith. In describing a temporal relationship, for example, when a temporal predecessor relationship is described as being “after,” “subsequent,” “next to,” “prior to,” or the like, unless “immediately” or “directly” is used, cases that are not continuous or sequential can also be included.

As used herein, the terms “connected” and “coupled” are intended to have the broadest possible meaning. Specifically, the phrase “A is connected to B” encompasses both a direct connection-where no intervening components or elements are present-and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner. For example, the term “in contact with,” as used herein, encompasses both “indirect contact” and “direct contact.” Accordingly, when the phrase “A is in contact with B” is used, it implies that other components may be present between A and B, unless explicitly specified as “A is in direct contact with B.”

Although the terms first, second, and the like are used to describe various components, these components are not substantially limited by these terms. These terms are used only to distinguish one component from another component, and may not define any order or sequence. Therefore, a first component described below can substantially be a second component within the technical spirit of the present disclosure.

Features of various embodiments of the present disclosure can be partially or entirely united or combined with each other, technically various interlocking and driving are possible, and each of the embodiments can be independently implemented with respect to each other or implemented together in a related relationship.

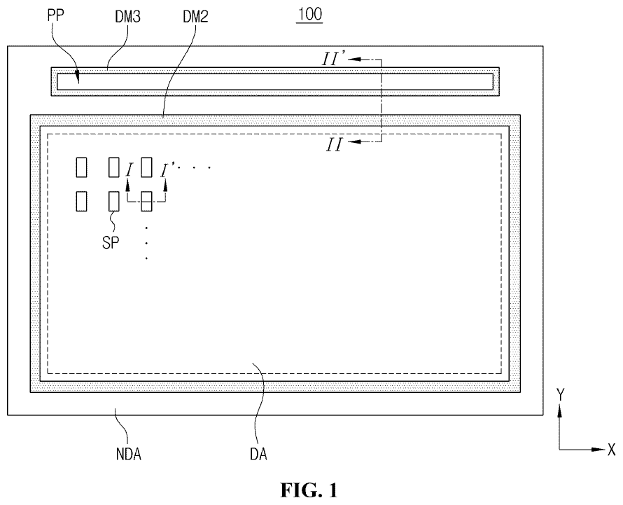

Hereinafter, exemplary embodiments of the present disclosure will be described in detail with reference to accompanying drawings. In particular, FIG. 1 is a view schematically showing a display device according to an embodiment of the present disclosure. The display device can be a micro LED (light-emitting diode) display device or a mini LED display device. However, embodiments of the present disclosure are not limited thereto.

In FIG. 1, the display device 100 includes a display area DA displaying an image and a non-display area NDA outside the display area DA. In particular, the non-display area NDA can surround at least one side of the display area DA. Also, the display area DA includes a plurality of sub-pixels SP arranged in a first direction X and in a second direction Y crossing the first direction X. At least one thin film transistor and a light-emitting element is also provided in each sub-pixel SP.

Also, each sub-pixel SP can display one color, and a plurality of sub-pixels displaying different colors can constitute one pixel. For example, one pixel can include three sub-pixels SP, and the three sub-pixels SP can be red, green, and blue sub-pixels, respectively. However, embodiments of the present disclosure are not limited thereto. In addition, a plurality of signal lines extending the first direction X and/or the second direction Y are provided in the display area DA and are electrically connected to the thin film transistor and/or the light-emitting element of each sub-pixel SP. The signal lines can thus transmit signal voltages from a driving portion to the thin film transistor and/or the light-emitting element.

Further, the driving portion can be attached to the non-display area NDA corresponding to one side of the display device 100, for example, an upper side of the display device 100 in the context of the figure. The driving portion can be provided as a chip on film (COF) type in which a driver integrated circuit ship (driver IC ship) is mounted on a base film. Alternatively, the driving portion can be provided as a chip on glass (COG) type or a tape carrier package (TCP) type.

Also, to connect the driving portion to the plurality of signal lines of the display area DA, a pad portion PP can be provided in the non-display area NDA. A plurality of pad electrodes can be provided in the pad portion PP. Further, the display device 100 can also include a plurality of dams. Specifically, a first dam can be provided in the display area DA and correspond to each sub-pixel SP, and the light-emitting element can be included inside the dam. As shown in FIG. 1, a second dam DM2 and a third dam DM3 can also be provided in the non-display area NDA. That is, the second dam DM2 can surround the display area DA, and the third dam DM3 can surround the pad portion PP.

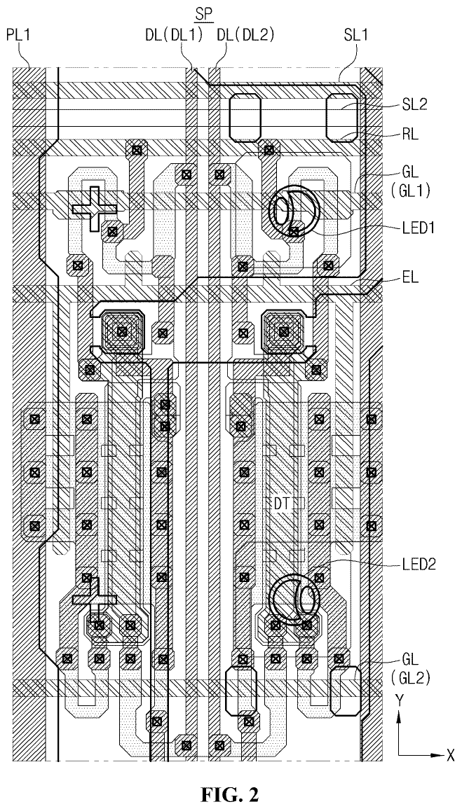

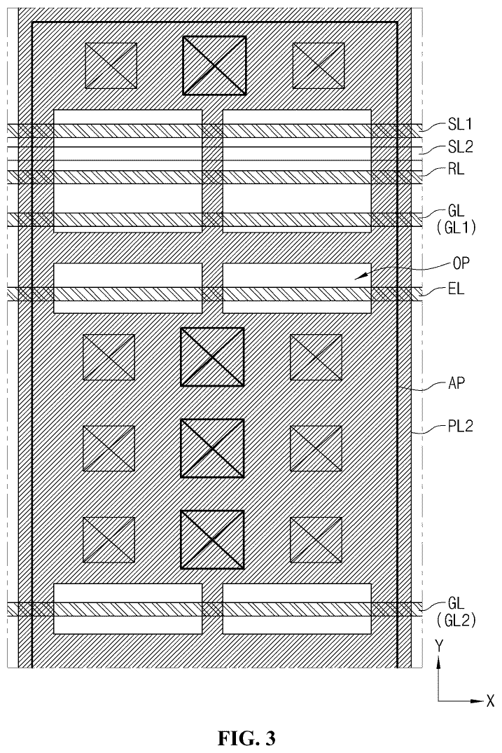

Also, the first dam, the second dam DM2, and the third dam DM3 can be used to form an organic insulating material in a desired area, and this will be described in detail later. A planar configuration of a display area of a display device according to an embodiment of the present disclosure will be described with reference to FIGS. 2 and 3, which are schematic plan views of a display device according to an embodiment of the present disclosure. In particular, FIG. 2 shows a sub-pixel provided in a display area, and FIG. 3 shows a power line provided in the display area.

As shown in FIGS. 2 and 3, the display device 100 can include a gate line GL, a reference line RL, and an emission line EL extending in a first direction X, and a data line DL and a first power line PL1 extending in a second direction Y. As shown, the data line DL and the first power line PL1 can cross the gate line GL, the reference line RL, and the emission line EL. Also, the gate line GL can include first and second gate lines GL1 and GL2. As shown, the first gate line GL1 can be disposed between the reference line RL and the emission line EL, and the emission line EL can be disposed between the first gate line GL1 and the second gate line GL2.

In addition, the data line DL can include first and second data lines DL1 and DL2. As shown, the first data line DL1 can be disposed between the second data line DL2 and the first power line PL1. Also, the first power line PL1 can have a wider width than the first and second data lines DL1 and DL2. The first power line PL1 can transmit a low potential voltage VSS.

In addition, first and second signal lines SL1 and SL2 can be further provided to extend in the first direction X. In particular, the first and second signal lines SL1 and SL2 can be a part of a gate driving portion for generating signals, which are applied to the gate line GL and/or the emission line EL. However, embodiments of the present disclosure are not limited thereto, and the first and second signal lines SL1 and SL2 can be omitted.

In addition, a second power line PL2 can extend in the second direction Y. As shown in FIG. 2, the second power line PL2 can be spaced apart from the data line DL and the first power line PL1 and can overlap and cross the gate line GL, the reference line RL, the emission line EL, and the first and second signal lines SL1 and SL2. Also, the second power line PL2 can have a wider width than each of the first data line DL1, the second data line DL2, and the first power line PL1. Thus, the second power line PL2 can transmit a high potential voltage VDD.

In addition, the second power line PL2 can have at least one opening OP corresponding to the gate line GL, the reference line RL, the emission line EL, and the first and second signal lines SL1 and SL2. Further, an auxiliary pattern AP can be provided to overlap the second power line PL2. The auxiliary pattern AP can overlap and cross the gate line GL, the reference line RL, the emission line EL, and the first and second signal lines SL1 and SL2. The auxiliary pattern AP can be in contact with the second power line PL2 through a plurality of contact holes.

In addition, at least one transistor DT and first and second light-emitting elements LED1 and LED2 can be provided and can be selectively connected to the lines GL, EL, RL, DL, PL1, and PL2. That is, the display device 100 according to the embodiment of the present disclosure can include two light-emitting elements LED1 and LED2 emitting the same color in one sub-pixel SP.

In addition, the first and second light-emitting elements LED1 and LED2 can emit light at the same time to implement an image. Alternatively, only one of two light-emitting elements LED1 and LED2 can emit light to implement an image. In this instance, one of two light-emitting elements LED1 and LED2 can be a main light-emitting element, and the other can be a redundancy light-emitting element that emits light when the main light-emitting element is defective.

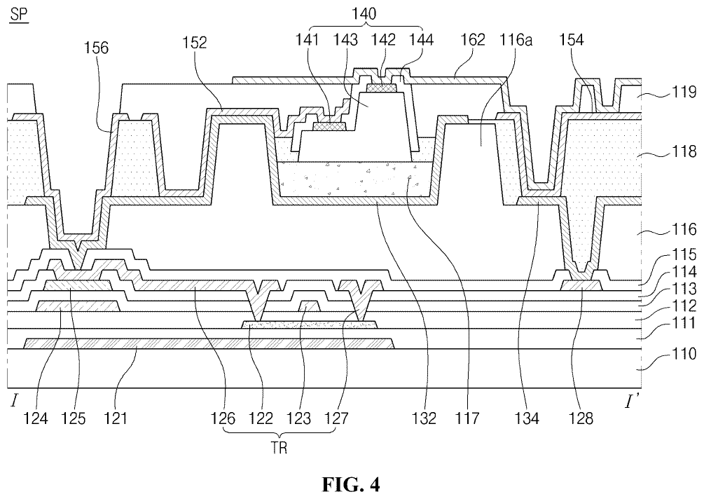

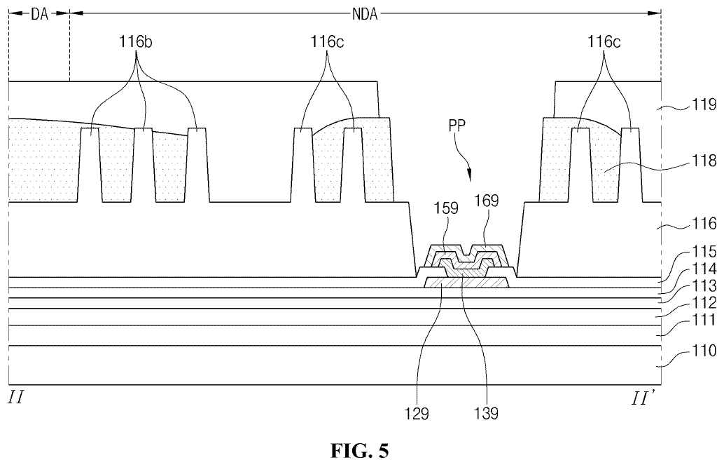

Next, a cross sectional configuration of a display device according to an embodiment of the present disclosure will be described in detail with reference to FIGS. 4 and 5, in which FIG. 4 is a schematic cross-sectional view of a sub-pixel in a display area of a display device according to a first embodiment of the present disclosure and shows a cross-section corresponding to line I-I′ of FIG. 1, and FIG. 5 is a schematic cross-sectional view of a non-display area of the display device according to the first embodiment of the present disclosure and shows a cross-section corresponding to line II-II′ of FIG. 1.

As shown in FIGS. 4 and 5, the display device according to the first embodiment of the present disclosure includes a substrate 110 provided with a display area DA and a non-display area NDA. A sub-pixel SP is also provided in the display area DA, and a pad portion PP is provided in the non-display area NDA. A thin film transistor TR, a light-emitting element 140, and a first dam 116a are also provided in the sub-pixel SP of the display area DA, and a second dam 116b and a third dam 116c can be provided in the non-display area NDA.

Specifically, as shown in FIG. 4, a light-shielding layer 121 can be provided in the sub-pixel SP on the substrate 110. Also, the substrate 110 can be a glass substrate or a plastic substrate. For example, polyimide can be used for the plastic substrate, and the plastic substrate can have a stacked structure including at least one polyimide layer and at least one inorganic layer. However, embodiments of the present disclosure are not limited thereto.

In addition, the light-shielding layer 121 can be formed of a conductive material such as metal. For example, the light-shielding layer 121 can be formed of one or more of: aluminum (Al), copper (Cu), molybdenum (Mo), titanium (Ti), chromium (Cr), nickel (Ni), tungsten (W), and an alloy thereof. The light-shielding layer 121 can also have a single-layered structure or a multiple-layered structure.

As shown in FIGS. 4 and 5, a buffer layer 111 can be provided on the light-shielding layer 121. For example, the buffer layer 111 can be disposed substantially all over the substrate 110. Accordingly, the buffer layer 111 can be disposed in both the display area DA and the non-display area NDA. The buffer layer 111 can also be formed as a single layer or multiple layers of an inorganic insulating material. For example, the inorganic insulating material of the buffer layer 111 can include silicon nitride (SiNx), silicon oxide (SiOx), or silicon oxynitride (SiON).

An active layer 122 can also be provided in the sub-pixel SP on the buffer layer 111. As shown, the active layer 122 can overlap the light-shielding layer 121, and the light-shielding layer 121 can block light incident on the active layer 122 and prevent the active layer 122 from deteriorating due to the light. The active layer 122 can include a channel region at its central part and source and drain regions at both sides of the channel region. Also, the active layer 122 can be formed of an oxide semiconductor material. Alternatively, the active layer 122 can be formed of polycrystalline silicon, and in this case, both ends of the active layer 122 can be doped with impurities.

Further, a gate insulation layer 112 can be provided on the active layer 122 and the buffer layer 111. For example, the gate insulation layer 112 can be disposed substantially all over the substrate 110. Accordingly, the gate insulation layer 112 can be disposed in both the display area DA and the non-display area NDA. The gate insulation layer 112 can also be formed as a single layer or multiple layers of an inorganic insulating material. For example, the inorganic insulating material of the gate insulation layer 112 can include silicon nitride (SiNx), silicon oxide (SiOx), or silicon oxynitride (SiON).

In addition, a gate electrode 123 and a first capacitor electrode 124 can be formed in the sub-pixel SP on the gate insulation layer 112. For example, the gate electrode 123 can overlap the active layer 122 and can be disposed to correspond to the central part of the active layer 122. Accordingly, the gate electrode 123 can also overlap the light-shielding layer 121. The first capacitor electrode 124 can also be spaced apart from the active layer 122 and can overlap the light-shielding layer 121.

Further, the gate electrode 123 and the first capacitor electrode 124 can be formed of a conductive material such as metal. For example, the gate electrode 123 and the first capacitor electrode 124 can be formed of one or more of: aluminum (Al), copper (Cu), molybdenum (Mo), titanium (Ti), chromium (Cr), nickel (Ni), tungsten (W), and an alloy thereof. The gate electrode 123 and the first capacitor electrode 124 can also have a single-layered structure or a multiple-layered structure.

In addition, a first interlayer insulation layer 113 can be provided on the gate electrode 123 and the first capacitor electrode 124. For example, the first interlayer insulation layer 113 can be disposed substantially all over the substrate 110. Accordingly, the first interlayer insulation layer 113 can be disposed in both the display area DA and the non-display area NDA. The first interlayer insulation layer 113 can also be formed as a single layer or multiple layers of an inorganic insulating material. For example, the inorganic insulating material of the first interlayer insulation layer 113 can include silicon nitride (SiNx), silicon oxide (SiOx), or silicon oxynitride (SiON).

Further, a second capacitor electrode 125 can be provided in the sub-pixel SP on the first interlayer insulation layer 113. For example, the second capacitor electrode 125 can overlap the first capacitor electrode 124 to thereby form a storage capacitor with the first interlayer insulation layer 113 therebetween as a dielectric. The second capacitor electrode 125 can also overlap the light-shielding layer 121.

In addition, the second capacitor electrode 125 can be formed of a conductive material such as metal. For example, the second capacitor electrode 125 can be formed of one or more of: aluminum (Al), copper (Cu), molybdenum (Mo), titanium (Ti), chromium (Cr), nickel (Ni), tungsten (W), and an alloy thereof. The second capacitor electrode 125 can have a single-layered structure or a multiple-layered structure.

Also, a second interlayer insulation layer 114 can be provided on the second capacitor electrode 125. For example, the second interlayer insulation layer 114 can be disposed substantially all over the substrate 110. Accordingly, the second interlayer insulation layer 114 can be disposed in both the display area DA and the non-display area NDA. The second interlayer insulation layer 114 can also be formed as a single layer or multiple layers of an inorganic insulating material. For example, the inorganic insulating material of the second interlayer insulation layer 114 can include silicon nitride (SiNx), silicon oxide (SiOx), or silicon oxynitride (SiON).

Further, a source electrode 126, a drain electrode 127, and a power line 128 can be provided in the sub-pixel SP on the second interlayer insulation layer 114. The source electrode 126 and the drain electrode 127 can be spaced apart from each other with the gate electrode 123 positioned therebetween and can be electrically connected to both ends of the active layer 122 through contact holes provided in the gate insulation layer 112 and the first and second interlayer insulation layers 113 and 114, respectively.

In addition, the source electrode 126 can extend to overlap the first and second capacitor electrodes 124 and 125 and can be in contact with the second capacitor electrode 125 through a contact hole provided in the second interlayer insulation layer 114. The active layer 122, the gate electrode 123, the source electrode 126, and the drain electrode 127 can constitute the thin film transistor TR. The thin film transistor TR can be a driving transistor, but embodiments of the present disclosure are not limited thereto.

In addition, the power line 128 can be spaced apart from the thin film transistor TR and the light-shielding layer 121. The power line 128 can transmit a high potential voltage VDD. Also, the source electrode 126, the drain electrode 127, and the power line 128 can be formed of a conductive material such as metal. For example, the source electrode 126, the drain electrode 127, and the power line 128 can be formed of one or more of: aluminum (Al), copper (Cu), molybdenum (Mo), titanium (Ti), chromium (Cr), nickel (Ni), tungsten (W), and an alloy thereof. The source electrode 126, the drain electrode 127, and the power line 128 can have a single-layered structure or a multiple-layered structure.

Further, as shown in FIG. 5, in the non-display area NDA, a pad electrode 129 can be provided in the pad portion PP on the second interlayer insulation layer 114. In particular, the pad electrode 129 can be formed of the same material and on the same layer as the source and drain electrodes 126 and 127. The pad electrode 129 can also be connected to one of a plurality of lines provided in the display area DA.

A passivation layer 115 can also be provided on source electrode 126, the drain electrode 127, the power line 128, and the pad electrode 129. For example, the passivation layer 115 can be disposed substantially all over the substrate 110. Accordingly, the passivation layer 115 can be disposed in both the display area DA and the non-display area NDA. The passivation layer 115 can also partially expose the source electrode 126 and the power line 128 in the sub-pixel SP of the display area DA and can partially expose the pad electrode 129 in the non-display area NDA.

Further, the passivation layer 115 can be formed as a single layer or multiple layers of an inorganic insulating material. For example, the inorganic insulating material of the passivation layer 115 can include silicon nitride (SiNx), silicon oxide (SiOx), or silicon oxynitride (SiON).

An overcoat layer 116 can also be provided on the passivation layer 115. For example, the overcoat layer 116 can be disposed substantially all over the substrate 110. Accordingly, the overcoat layer 116 can be disposed in both the display area DA and the non-display area NDA. The overcoat layer 116 can partially expose the source electrode 126 and the power line 128 in the sub-pixel SP of the display area DA together with the passivation layer 115 and can partially expose the passivation layer 115 on the source electrode 126 and the power line 128. In addition, the overcoat layer 116 can be removed to correspond to the pad portion PP in the non-display area NDA and can partially expose the passivation layer 115 on the pad electrode 129 in the non-display area NDA.

Further, the overcoat layer 116 can eliminate a step difference due to the layers thereunder and can have a substantially flat top surface. The overcoat layer 116 can be formed of an organic insulating material such as photosensitive acrylic polymer (photo acryl). As shown in FIGS. 4 and 5, the overcoat layer 116 can have a first dam 116a in the display area DA and a second dam 116b and a third dam 116c in the non-display area NDA.

In more detail, as shown in FIG. 4, the first dam 116a corresponds to the sub-pixel SP and surrounds the light-emitting element 140. Also, as shown in FIG. 5, the second dam 116b can be adjacent to the display area DA and surround the display area DA. The third dam 116c can also be spaced apart from the second dam 116b and can surround the pad portion PP.

In addition, the first dam 116a can include one dam pattern and partially overlap the thin film transistor TR. However, embodiments of the present disclosure are not limited thereto, and in other embodiments, the first dam 116a can be spaced apart from the thin film transistor TR.

In addition, each of the second dam 116b and the third dam 116c can include a plurality of dam patterns spaced apart from each other. In this instance, the number of dam patterns of the second dam 116b can be greater than the number of dam patterns of the third dam 116c. For example, the second dam 116b can include three dam patterns, and the third dam 116c can include two dam patterns. However, embodiments of the present disclosure are not limited thereto, and in other embodiments, the number of dam patterns of the second dam 116b and the third dam 116c can vary. Further, in another embodiment, the second dam 116b and the third dam 116c can include the same number of dam patterns.

Also, a reflection electrode 132 and a first connection electrode 134 can be provided in the sub-pixel SP on the overcoat layer 116 having the first dam 116a, the second dam 116b, and the third dam 116c. The reflection electrode 132 can overlap the thin film transistor TR and the first and second capacitor electrodes 124 and 125. In addition, the reflection electrode 132 can be in contact with the source electrode 126 over the first and second capacitor electrodes 124 and 125 through a contact hole provided in the passivation layer 115 and the overcoat layer 116. Accordingly, the reflection electrode 132 can be electrically connected to the second capacitor electrode 125 through the source electrode 126.

Further, the reflection electrode 132 can extend and also be provided inside the first dam 116a. Accordingly, the reflection electrode 132 can be in contact with a top surface of the overcoat layer 116 inside the first dam 116a. In addition, the reflection electrode 132 can partially overlap the first dam 116a and partially cover and contact the first dam 116a. In this instance, the reflection electrode 132 can be in contact with top and side surfaces of the first dam 116a.

Also, the first connection electrode 134 can overlap the power line 128and be in contact with and electrically connected to the power line 128 through a contact hole provided in the passivation layer 115 and the overcoat layer 116. The first connection electrode 134 can also be spaced apart from the first dam 116a.

In addition, the reflection electrode 132 and the first connection electrode 134 can be formed of a metal having relatively high reflectance. For example, the reflection electrode 132 and the first connection electrode 134 can be formed of aluminum (Al), silver (Ag), or chromium (Cr). Further, in the non-display area NDA, a first auxiliary pad 139 can be provided in the pad portion PP. The first auxiliary pad 139 can be formed of the same material and on the same layer as the reflection electrode 132 and the first connection electrode 134. The first auxiliary pad 139 can be disposed in a hole of the overcoat layer 116 and can be in contact with the pad electrode 129 through a contact hole provided in the passivation layer 115.

An adhesive layer 117 can be provided on the reflection electrode 132 in the sub-pixel SP. The adhesive layer 117 can be disposed only inside the first dam 116a and not be provided in the display area DA excluding the inside of the first dam 116a and the non-display area NDA. The adhesive layer 117 can fix the light-emitting element 140 that is transferred thereon.

The adhesive layer 117 can be formed of a photocurable adhesive material that is cured by light. For example, the adhesive layer 117 can be formed of photosensitive acrylic polymer (photo acryl). However, embodiments of the present disclosure are not limited thereto. Alternatively, the adhesive layer 117 can be formed of one of a polyimide (PI) resin, an epoxy resin, a urethane resin, and a polydimethylsiloxane (PDMS) resin.

In addition, the light-emitting element 140 can be provided on the adhesive layer 117 in the sub-pixel SP. The light-emitting element 140 can be disposed inside the first dam 116a and can be surrounded by the first dam 116a. The light-emitting element 140 can overlap the reflection electrode 132. In addition, the light-emitting element 140 can also overlap the thin film transistor TR and the light-shielding layer 121.

The light-emitting element 140 can be provided in the form of a micro light-emitting diode chip (micro LED chip or uLED chip) including an n-electrode, an n-type layer, an active layer, a p-type layer, and a p-electrode. The light-emitting element 140 can have a lateral structure in which the n-electrode and the p-electrode are provided on the same side (for example, a second side opposite to a first side facing the substrate 110) and light is emitted through the second side provided with the n-electrode and the p-electrode (for example, the second side opposite to the first side facing the substrate 110).

However, embodiments of the present disclosure are not limited thereto. In other embodiments, the light-emitting element 140 can have a flip-chip structure in which the n-electrode and the p-electrode are provided on the same side (for example, the first side facing the substrate 110) and light is emitted through the second side opposite to the first side provided with the n-electrode and the p-electrode. Alternatively, the light-emitting element 140 can have a vertical structure in which the n-electrode and the p-electrode are provided on opposite sides (for example, a first side facing the substrate 110 and a second side opposite to the first side), respectively.

In addition, as shown in FIG. 4, the light-emitting element 140 can include a first element electrode 141, a second element electrode 142, a semiconductor layer 143, and a protection layer 144. The first element electrode 141 and the second element electrode 142 can be provided on the semiconductor layer 143 and can be spaced from each other. Also, the semiconductor layer 143 can have a step difference at its top surface. Further, the first element electrode 141 and the second element electrode 142 can be disposed at different heights. For example, the second element electrode 142 can be disposed higher than the first element electrode 141.

Here, the first element electrode 141 can be an n-electrode, and the second element electrode 142 can be a p-electrode. For example, the first element electrode 141 can be a cathode, and the second element electrode 142 can be an anode. However, embodiments of the present disclosure are not limited thereto. Alternatively, in other embodiments, the first element electrode 141 can be a p-electrode, and the second element electrode 142 can be an n-electrode. In this instance, the first element electrode 141 can be an anode, and the second element electrode 142 can be a cathode.

Further, the first element electrode 141 and the second element electrode 142 can be formed of a conductive material. For example, the first element electrode 141 and the second element electrode 142 can be formed of a transparent conductive material such as indium tin oxide (ITO) or indium zinc oxide (IZO). However, embodiments of the present disclosure are not limited thereto, and in other embodiments, the first element electrode 141 and the second element electrode 142 can be formed of a metal material such as titanium (Ti), gold (Au), silver (Ag), copper (Cu), or an alloy thereof.

In addition, the semiconductor layer 143 can include a first semiconductor layer, a light-emitting layer, and a second semiconductor layer. In particular, the first semiconductor layer and the second semiconductor layer can be formed by doping n-type or p-type impurities into a semiconductor material. For example, the first semiconductor layer and the second semiconductor layer can be formed by doping n-type or p-type impurities into gallium nitride (GaN), indium aluminum phosphide (InAlP), or gallium arsenide (GaAs). In addition, for example, the n-type impurities can be silicon (Si), germanium (Ge), or tin (Sn), and the p-type impurities can be magnesium (Mg), zinc (Zn), or beryllium (Be). However, embodiments of the present disclosure are not limited thereto.

Further, the light-emitting layer can be disposed between the first semiconductor layer and the second semiconductor layer. In particular, the light-emitting layer can receive electrons and holes from the first semiconductor layer and the second semiconductor layer, respectively, and emit light. The light-emitting layer can also be formed of a single quantum well (SQW) structure or a multi quantum well (MQW) structure. For example, the light-emitting layer can be formed of indium gallium nitride (InGaN) or gallium nitride (GaN), but is not limited thereto.

In addition, the protection layer 144 can be provided on the first element electrode 141, the second element electrode 142, and the semiconductor layer 143. As shown in FIG. 4, the protection layer 144 can cover and protect the first element electrode 141, the second element electrode 142, and the semiconductor layer 143 and can partially expose top surfaces of the first element electrode 141 and the second element electrode 142. The protection layer 144 can also be formed as a single layer or multiple layers of an inorganic insulating material. For example, the inorganic insulating material of the protection layer 144 can include silicon nitride (SiNx), silicon oxide (SiOx), or silicon oxynitride (SiON).

Next, a first planarization layer 118 can be provided on the adhesive layer 117 provided with the light-emitting element 140 thereon. For example, the first planarization layer 118 can be disposed substantially all over the display area DA and can be disposed both inside and outside the first dam 116a. The first planarization layer 118 can also surround a portion of a side surface of the light-emitting element 140 to fix and protect the light-emitting element 140. A height or thickness of the first planarization layer 118 can be smaller than a height or thickness of the light-emitting element 140. Also, the first planarization layer 118 can expose the first element electrode 141 and the second element electrode 142 of the light-emitting element 140.

Further, the height of the first planarization layer 118 inside the first dam 116a can be lower than the height of the first planarization layer 118 outside the first dam 116a. Also, a height of the first planarization layer 118 within inner surface of the first dam 116a is lower than the height of the first dam 116a. In addition, the first planarization layer 118 can expose the reflection electrode 132 on a top surface and/or a side surface of the first dam 116a. Also, the first planarization layer 118 can also be provided in the non-display area NDA. In the non-display area NDA, as shown in FIG. 5, the first planarization layer 118 can be provided inside the second dam 116 and inside the third dam 116c and is not provided between the second dam 116b and the third dam 116c. The first planarization layer 118 can also be provided between adjacent dam patterns of each of the second dam 116b and the third dam 116c and can be removed to correspond to the pad portion PP. That is, as shown in FIG. 5, the second dam 116b and the third dam 116c have a height set to block the planarization layer from being between the second dam 116b and the third dam 116c.

In addition, the first planarization layer 118 can be formed of an organic insulating material such as photosensitive acrylic polymer (photo acryl). Also, the first planarization layer 118 can have a substantially flat top surface and can be formed by a coating method. For example, the first planarization layer 118 can be formed by an inkjet coating method or a nozzle coating method, and in this instance, the second dam 116b and the third dam 116c can prevent a material of the first planarization layer 118 from overflowing to the outside.

Further, the first planarization layer 118 can have a property opposite to those of the protection layer 144 of the light-emitting element 140 with respect to water molecules and can have the same property as the adhesive layer 117 with respect to water molecules. For example, the protection layer 144 can have a hydrophilic property such that a contact angle with respect to a water droplet is smaller than 90 degrees, and the adhesive layer 117 and the first planarization layer 118 can have a hydrophobic property such that a contact angle with respect to a water droplet is greater than 90 degrees. Accordingly, it can facilitate the formation of the first planarization layer 118 and simplify the manufacturing process, and this will be described in detail later.

As shown in FIG. 4, a first electrode 152, a second connection electrode 154, and a contact electrode 156 can be provided in the sub-pixel SP on the first planarization layer 118. For example, the first electrode 152 can overlap the light-emitting element 140. The first electrode 152 can also be in contact with the first element electrode 141 of the light-emitting element 140 and can be spaced apart from the second element electrode 142 of the light-emitting element 140. In addition, the first electrode 152 can overlap the reflection electrode 132 and can be in contact with the reflection electrode 132.

In this instance, the first electrode 152 can partially overlap the first dam 116a and can be in contact with the reflection electrode 132 on the top surface and/or side surface of the first dam 116a. Alternatively, the first electrode 152 can be in contact with the reflection electrode 132 through a contact hole provided in the first planarization layer 118. The contact hole of the first planarization layer 118 can be provided between the first planarization layer 118 and the first dam 116a.

Accordingly, the first electrode 152 can be electrically connected to the source electrode 126 of the thin film transistor TR and the second capacitor electrode 125 through the reflection electrode 132. The first element electrode 141 of the light-emitting element 140 can be electrically connected to the source electrode 126 of the thin film transistor TR and the second capacitor electrode 125 through the first electrode 152 and the reflection electrode 132.

In addition, the second connection electrode 154 can overlap the first connection electrode 134 and can be in contact with the first connection electrode 134 through a contact hole provided in the first planarization layer 118. Accordingly, the second connection electrode 154 can be electrically connected to the power line 128 through the first connection electrode 134.

Further, the contact electrode 156 can overlap the reflection electrode 132, the source electrode 126, and the first and second capacitor electrodes 124 and 125. The contact electrode 156 can also be in contact with the reflection electrode 132 through a contact hole provided in the first planarization layer 118. Accordingly, the contact electrode 156 can be electrically connected to the source electrode 126 of the thin film transistor TR and the second capacitor electrode 125 through the reflection electrode 132. In addition, the contact electrode 156 can be electrically connected to the first electrode 152 through the reflection electrode 132.

The first electrode 152, the second connection electrode 154, and the contact electrode 156 can be formed of a transparent conductive material such as indium tin oxide (ITO) or indium zinc oxide (IZO). Alternatively, the first electrode 152, the second connection electrode 154, and the contact electrode 156 can be formed of a metal such as aluminum (Al), copper (Cu), molybdenum (Mo), titanium (Ti), chromium (Cr), nickel (Ni), tungsten (W), or an alloy thereof.

Further, in the non-display area NDA, a second auxiliary pad 159 can be provided in the pad portion PP. The second auxiliary pad 159 can be formed of the same material as the first electrode 152, the second connection electrode 154, and the contact electrode 156. The second auxiliary pad 159 can be disposed in the hole of the overcoat layer 116 and can cover and contact the first auxiliary pad 139.

Also, a second planarization layer 119 can be provided on the first electrode 152, the second connection electrode 154, and the contact electrode 156. For example, the second planarization layer 119 can be disposed substantially all over the substrate 110. Accordingly, the second planarization layer 119 can be disposed in both the display area DA and the non-display area NDA.

In addition, the second planarization layer 119 can be formed of an organic insulating material such as photosensitive acrylic polymer (photo acryl). The second planarization layer 119 can also have the same property as the first planarization layer 118 with respect to water molecules, for example, a hydrophobic property. The second planarization layer 119 can surround a portion of the side surface of the light-emitting element 140 to flatten a top surface of the substrate 110 on which the light-emitting element 140 is disposed together with the first planarization layer 118 and to fix and protect the light-emitting element 140 together with the adhesive layer 117 and the first planarization layer 118.

Further, the second planarization layer 119 can cover the light-emitting element 140 and the first electrode 152 and can expose a part of the light-emitting element 140. Specifically, the second planarization layer 119 can cover the first element electrode 141 of the light-emitting element 140, the first electrode 152, and the first dam 116a and can partially expose the second element electrode 142 of the light-emitting element 140. In addition, the second planarization layer 119 can partially expose the second connection electrode 154 and the contact electrode 156.

In the non-display area NDA, the second planarization layer 119 can cover the first planarization layer 118, the second dam 116b, and the third dam 116c. Also, the second planarization layer 119 can also be provided between the second dam 116b and the third dam 116c and can be in contact with the top surface of the overcoat layer 116 between the second dam 116b and the third dam 116c. The second planarization layer 119 can also be removed to correspond to the pad portion PP.

Further, the second planarization layer 119 is provided between the second dam 116b and the third dam 116c in the non-display area NDA, but embodiments of the present disclosure are not limited thereto. In other embodiments, the second planarization layer 119 can be removed between the second dam 116b and the third dam 116c. Alternatively, the second planarization layer 119 can be completely removed in the non-display area NDA.

Next, a second electrode 162 can be provided in the sub-pixel SP on the second planarization layer 119. For example, the second electrode 162 can overlap the light-emitting element 140, the first electrode 152, and the second connection electrode 154. Specifically, the second electrode 162 can overlap the first and second element electrode 141 and 142 of the light-emitting element 140 and can be in contact with the exposed second element electrode 142. In addition, the second electrode 162 can also overlap the first electrode 152 and the first dam 116a and thus overlap the reflection electrode 132.

In addition, the second electrode 162 can extend to overlap the second connection electrode 154. In particular, the second electrode 162 can be in contact with and electrically connected to the second connection electrode 154 through a contact hole provided in the second planarization layer 119. Accordingly, the second electrode 162 can be electrically connected to the first connection electrode 134 through the second connection electrode 154. The second element electrode 142 of the light-emitting element 140 can also be electrically connected to the power line 128 through the second electrode 162 and the first and second connection electrodes 134 and 154.

In this instance, the second electrode 162 can be in contact with the second connection electrode 154 through at least two contact holes, thereby improving contact properties between the second electrode 162 and the second connection electrode 154. The second electrode 162 can also be formed of a transparent conductive material such as indium tin oxide (ITO) or indium zinc oxide (IZO). Alternatively, the second electrode 162 can be formed of a metal such as aluminum (Al), copper (Cu), molybdenum (Mo), titanium (Ti), chromium (Cr), nickel (Ni), tungsten (W), or an alloy thereof.

As such, in the display device according to the first embodiment of the present disclosure, by providing the first dam 116a, providing the adhesive layer 117 inside the first dam 116a, and transferring the light-emitting element 140 on the adhesive layer 117, the transfer location of the light-emitting element 140 can be specified, and the light-emitting element 140 can be easily transferred to a desired region. In addition, by providing the second dam 116b surrounding the display area DA and forming the first planarization layer 118 using a material with a different property from the protection layer 144, it is possible to facilitate the formation of the first planarization layer 118 and simplify the manufacturing process

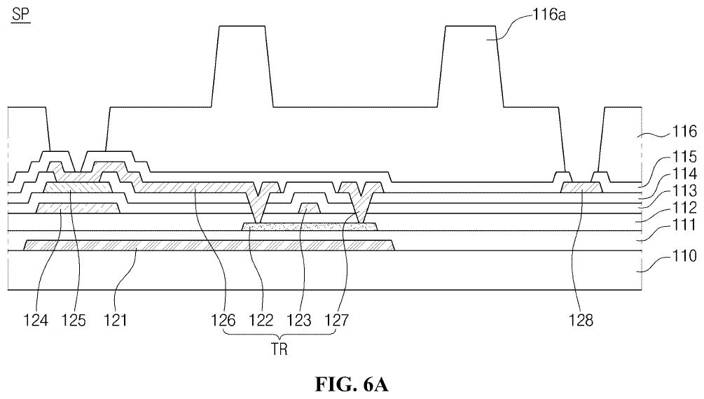

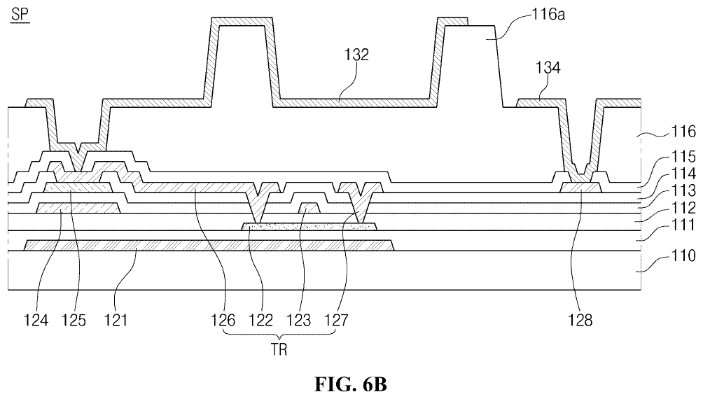

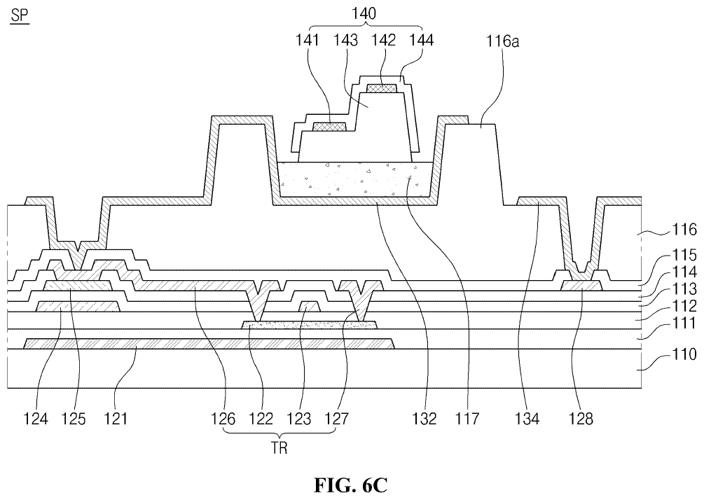

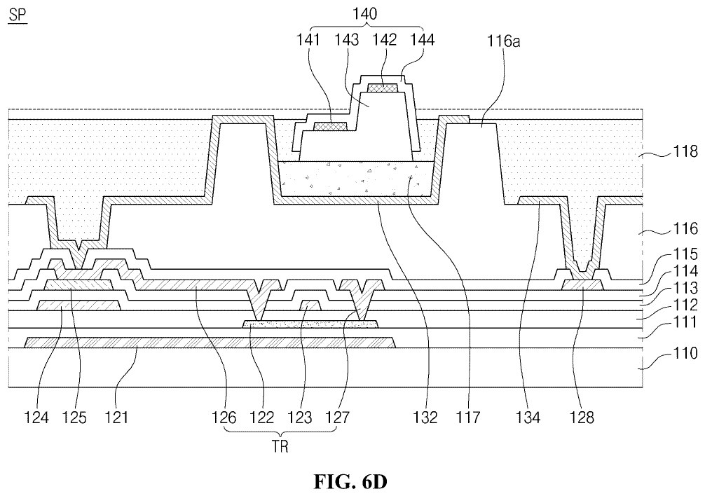

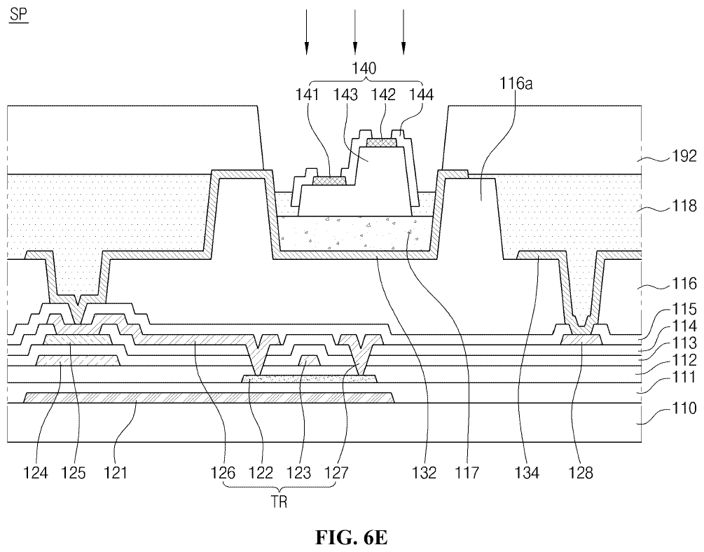

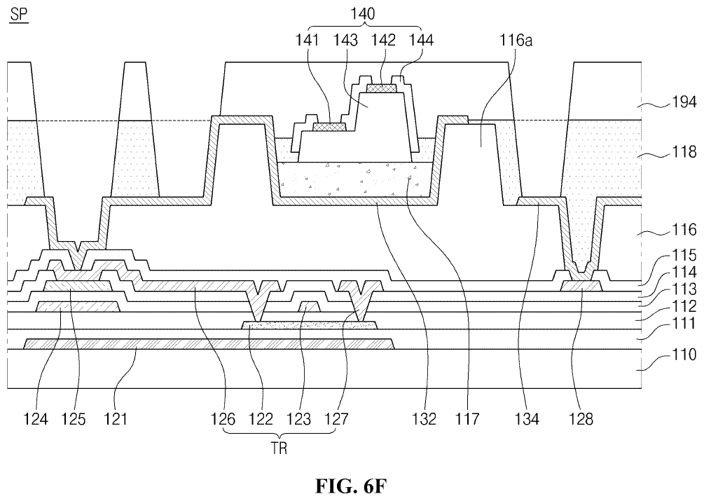

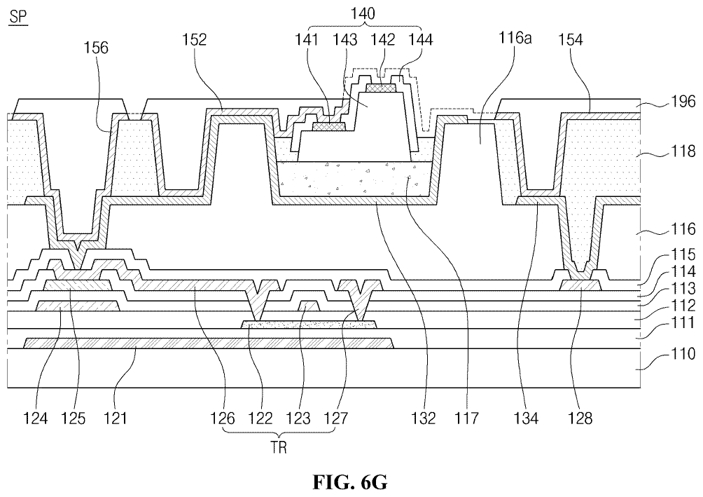

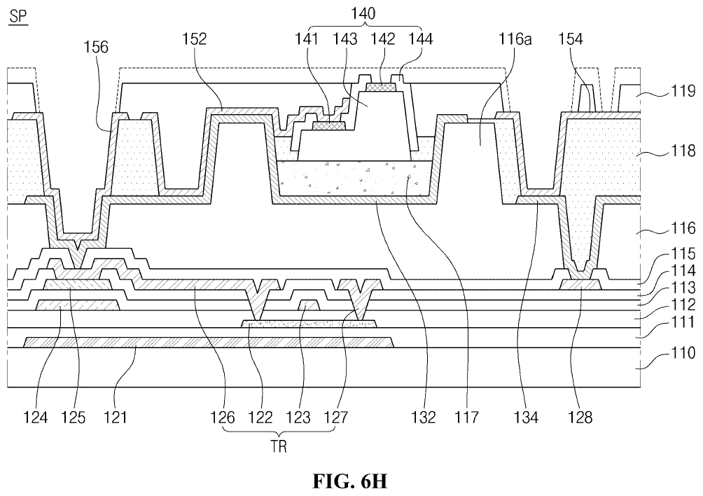

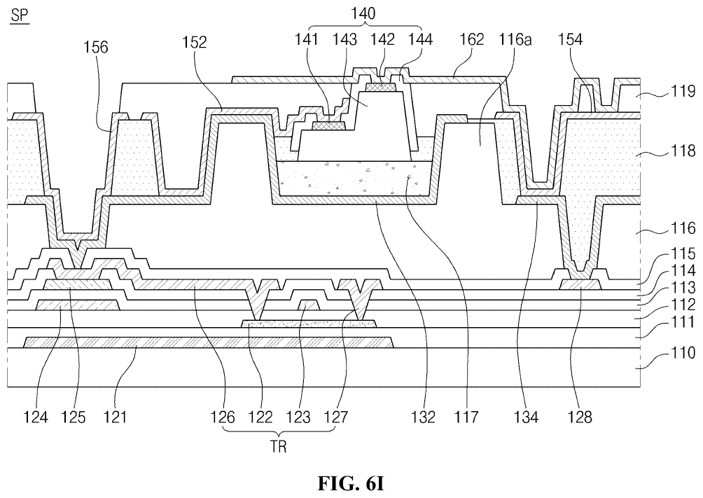

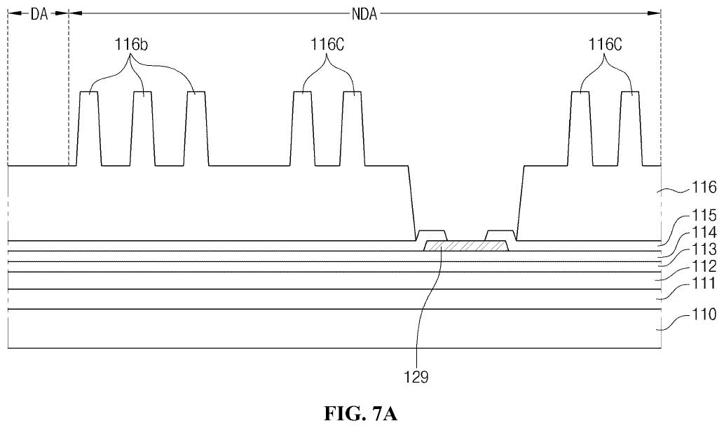

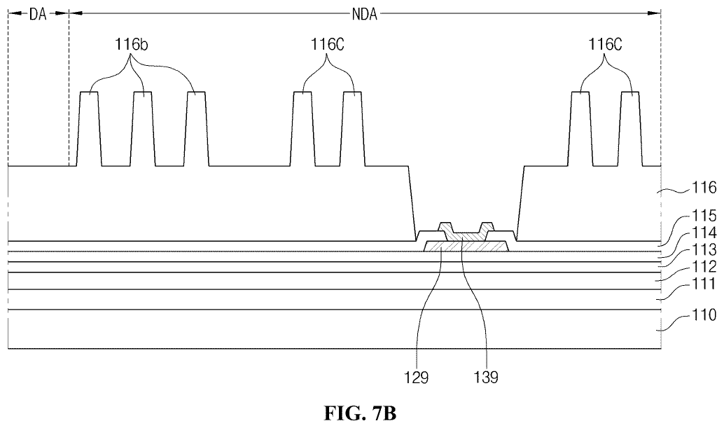

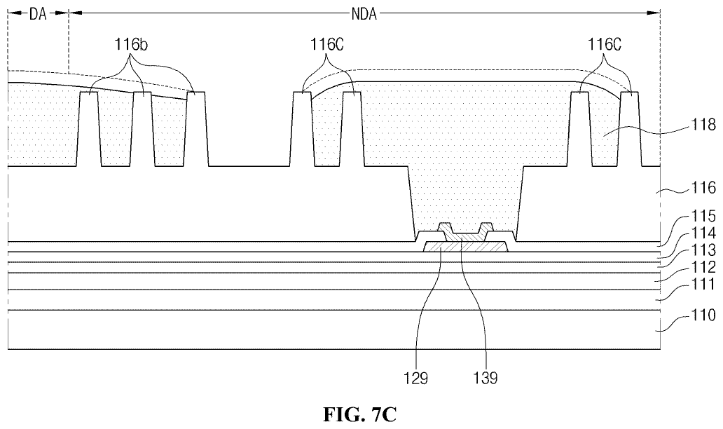

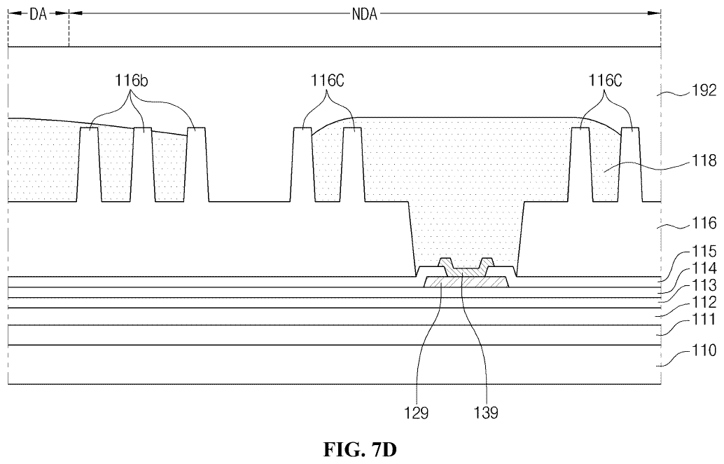

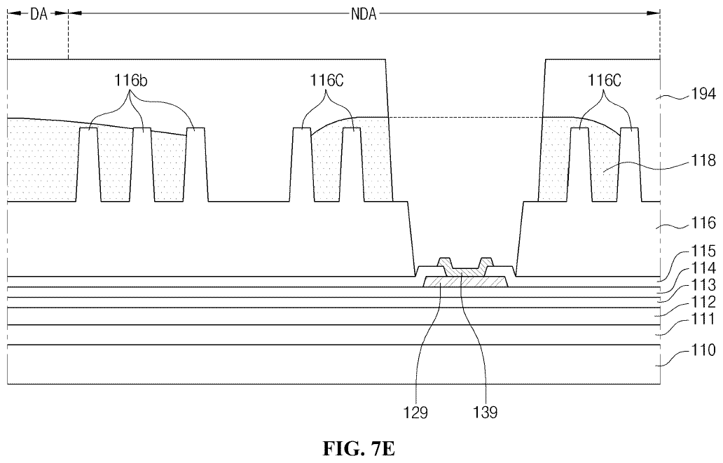

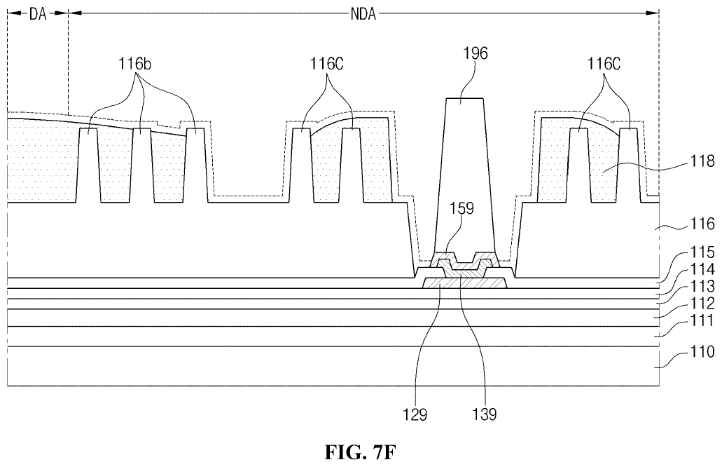

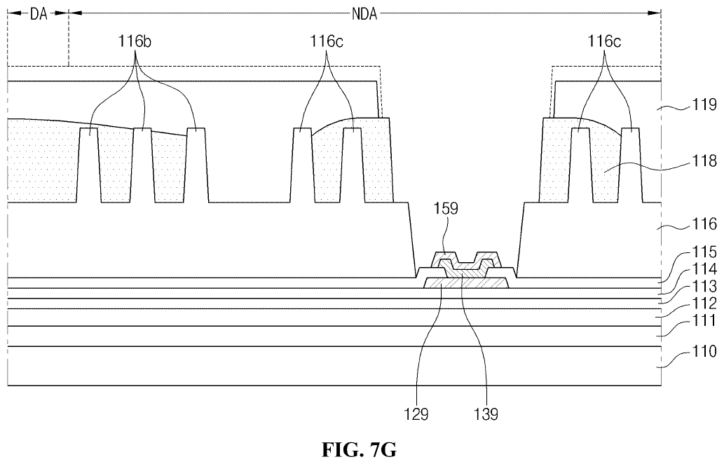

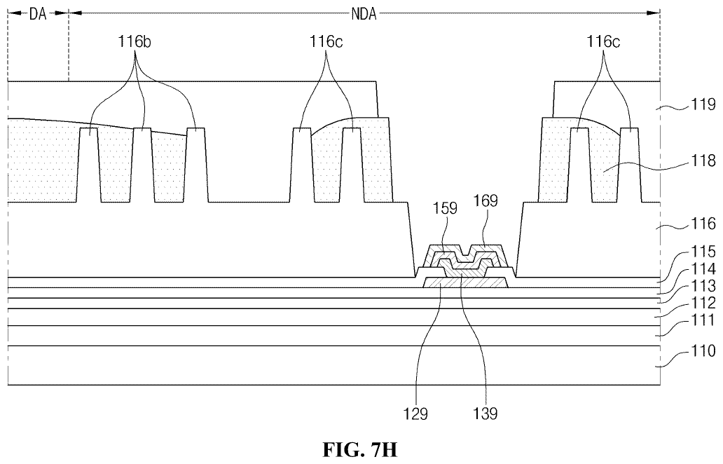

A method of manufacturing the display device according to the first embodiment of the present disclosure will be described with reference to FIGS. 6A to 6I and FIGS. 7A to 7H. In particular, FIGS. 6A to 6I are schematic cross-sectional views of a display device in steps of manufacturing the same according to the first embodiment of the present disclosure and show cross-sections corresponding to line I-I′ of FIG. 1, and FIGS. 7A to 7H are schematic cross-sectional views of the display device in steps of manufacturing the same according to the first embodiment of the present disclosure and show cross-sections corresponding to line II-II′ of FIG. 1.

As shown in FIG. 6A 7A, by repeating steps of depositing a thin film and selectively removing it through a photolithography process, the light-shielding layer 121, the buffer layer 111, the active layer 122, the gate insulation layer 112, the gate electrode 123 and the first capacitor electrode 124, the first interlayer insulation layer 113, the second capacitor electrode 125, the second interlayer insulation layer 114, the source and drain electrodes 126 and 127, the power line 128 and the pad electrode 129, and the passivation layer 115 can be sequentially formed on the substrate 110 provided with the display area DA and the non-display area NDA.

Next, the overcoat layer 116 can be formed on the passivation layer 115 by applying an organic insulating material and can be selectively removed through a photolithography process, thereby forming the first dam 116a, the second dam 116b, and the third dam 116c. In addition, the overcoat layer 116 and the passivation layer 115 thereunder can be selectively patterned, thereby forming the contact holes exposing the source electrode 126, the power line 128, and the pad electrode 129, respectively.

In addition, the overcoat layer 116 can be exposed to light through a halftone mask including a light-blocking portion, a light-transmitting portion, and a half light-transmitting portion. The overcoat layer 116 can have negative photosensitivity in which a portion exposed to light remains after developing. In this instance, the contact holes of the overcoat layer 116 can correspond to the light-blocking portion, the first, second, and third dams 116a, 116b, and 116c can correspond to the light-transmitting portion, and the remaining part of the overcoat layer 116 can correspond to the half light-transmitting portion.

However, embodiments of the present disclosure are not limited thereto. In other embodiments, the overcoat layer 116 can have positive photosensitivity in which a portion exposed to light is removed after developing. In this instance, the contact holes of the overcoat layer 116 can correspond to the light-transmitting portion, and the first, second, and third dams 116a, 116b, and 116c can correspond to the light-blocking portion.

Next, in FIGS. 6B and 7B, by depositing a conductive material on the overcoat layer 116 and then patterning it through a photolithography process, the reflection electrode 132 and the first connection electrode 134 can be formed in the sub-pixel SP, and the first auxiliary pad 139 can be formed in the non-display area NDA. The reflection electrode 132 can be in contact with the source electrode 126. In addition, the reflection electrode 132 can extend and also be provided inside the first dam 116a. Also, the reflection electrode 132 can partially overlap and contact the first dam 116a and can be in contact with the top surface of the overcoat layer 116 inside the first dam 116a. In addition, the first connection electrode 134 can be in contact with the power line 128, and the first auxiliary pad 139 can be in contact with the pad electrode 129.

Next, in FIG. 6C, the adhesive layer 117 can be formed on the reflection electrode 132 inside the first dam 116a by applying an adhesive material, and the light-emitting element 140 can be transferred on the adhesive layer 117. The light-emitting element 140 can include the first element electrode 141, the second element electrode 142, the semiconductor layer 143, and the protection layer 144. Here, the protection layer 144 can cover the first and second element electrodes 141 and 142 without exposing them.

Next, in FIGS. 6D and 7C, the first planarization layer 118 can be formed over the substrate 110 on which the light-emitting element 140 is transferred by applying an organic insulating material. Further, the first planarization layer 118 can expose the protection layer 144 on the second element electrode 142. The first planarization layer 118 can also be formed inside the second dam 116b including the first dam 116a and also be formed inside the third dam 116c not formed between the second dam 116b and the third dam 116c.

In addition, the first planarization layer 118 can be formed by an inkjet coating method, and the applied material of the first planarization layer 118 can be prevented from overflowing to the outside by the second dam 116b and the third dam 116c. Further, the protection layer 144 can have a hydrophilic property, and the first planarization layer 118 and the adhesive layer 117 can have a hydrophobic property. Accordingly, the first planarization layer 118 can be formed relatively thinly or not formed on the protection layer 144 on the first element electrode 141 due to the different properties of the protection layer 144 and the first planarization layer 118. Also, the first planarization layer 118 can be stably formed on the adhesive layer 117 having the same property.

Then, the first planarization layer 118 can be partially removed from its top surface through an ashing process. Accordingly, a thickness of the first planarization layer 118 can be decreased, and the first planarization layer 118 can expose the protection layer 144 on the first and second element electrodes 141 and 142 of the light-emitting element 140. In this instance, the reflection electrode 132 on the first dam 116a not be covered and can also be exposed by the first planarization layer 118. Alternatively, if the first planarization layer 118 is not formed on the protection layer 144 on the first element electrode 141, the ashing process can be omitted.

Next, in FIGS. 6E and 7D, a first photoresist pattern 192 can be formed on the first planarization layer 118 through a photolithography process where photoresist is applied on the light-emitting element 140 and the first planarization layer 118, exposed to light, and developed. For example, the first photoresist pattern 192 can be formed substantially all over the substrate 110 excluding the light-emitting element 140 inside the first dam 116a. The first photoresist pattern 192 can also cover the first planarization layer 118 in the display area DA and the non-display area NDA and can expose the light-emitting element 140 inside the first dam 116a. In this instance, the first planarization layer 118 inside the first dam 116a can also be exposed.

Then, the protection layer 144 of the light-emitting element 140 exposed inside the first dam 116a can be selectively removed, thereby exposing the first and second element electrodes 141 and 142. Here, the protection layer 144 can be removed through a dry etching process. In this instance, the first planarization layer 118 inside the first dam 116a can also be partially removed, so that the height of the first planarization layer 118 inside the first dam 116a can be lower than the height of the first planarization layer 118 outside the first dam 116a.

Next, in FIGS. 6F and 7E, the first photoresist pattern 192 can be stripped and removed, and a second photoresist pattern 194 can be formed on the light-emitting element 140 and the first planarization layer 118 through a photolithography process where photoresist is applied, exposed to light, and developed. Also, the second photoresist pattern 194 can cover the light-emitting element 140, partially expose the first planarization layer 118 on the reflection electrode 132 and the first connection electrode 134, and partially expose the first planarization layer 118 inside the third dam 116c.

Then, the first planarization layer 118 can be selectively removed using the second photoresist pattern 194 as an etching mask, thereby partially exposing the reflection electrode 132 and the first connection electrode 134 and completely exposing the first auxiliary pad 139. Alternatively, the first auxiliary pad 139 can be partially exposed. In this instance, the first planarization layer 118 can be removed through a dry etching process.

Next, in FIGS. 6G and 7F, the second photoresist pattern 194 can be stripped and removed, and a conductive material layer can be formed substantially all over the substrate 110 by depositing a conductive material on the light-emitting element 140 and the first planarization layer 118. Then, a third photoresist pattern 196 can be formed on the conductive material layer through a photolithography process where photoresist is applied, exposed to light, and developed. The third photoresist pattern 196 can also partially expose the conductive material layer.

In addition, the third photoresist pattern 196 can cover the first element electrode 141 of the light-emitting element 140 and expose the second element electrode 142 without covering it. In this instance, to completely expose the second element electrode 142, the third photoresist pattern 196 can be partially removed by performing an ashing process. Further, the third photoresist pattern 196 can be formed only inside the third dam 116c in the non-display area NDA.

Next, by selectively removing the conductive material layer using the third photoresist pattern 196 as an etching mask, the first electrode 152, the second connection electrode 154, and the contact electrode 156 can be formed in the sub-pixel SP, and the second auxiliary pad 159 can be formed in the non-display area NDA. In addition, the first electrode 152 can be in contact with the first element electrode 141 and the reflection electrode 132, and the second connection electrode 154 can be in contact with the first connection electrode 134. Further, the contact electrode 156 can be in contact with the reflection electrode 132. In addition, the second auxiliary pad 159 can be in contact with the first auxiliary pad 139.

Next, in FIGS. 6H and 7G, the third photoresist pattern 196 can be stripped and removed. Also, the second planarization layer 119 can be formed on the first electrode 152, the second connection electrode 154, the contact electrode 156, and the second auxiliary pad 159 by applying an organic insulating material and then patterned through a photolithography process, thereby exposing the second connection electrode 154 and the contact electrode 156. In this instance, the second planarization layer 119 can cover the light-emitting element 140 and the first electrode 152.

In addition, the second planarization layer 119 can cover the second dam 116b and the third dam 116c in the non-display area NDA and can be removed inside the third dam 116c, thereby exposing the second auxiliary pad 159. However, embodiments of the present disclosure are not limited thereto, and in other embodiments, the second planarization layer 119 can be completely removed in the non-display area NDA.

Then, the second planarization layer 119 can be partially removed through an ashing process. Accordingly, the thickness of the second planarization layer 119 can be decreased, thereby exposing the second element electrode 142 of the light-emitting element 140. In this instance, a width of the second planarization layer 119 can also be decreased through the ashing process together with the thickness of the second planarization layer 119.

Further, the second planarization layer 119 can be formed by a coating method. For example, the second planarization layer 119 can be formed by a spin coating method or a slit coating method. In this instance, to stably form the second planarization layer 119, the second planarization layer 119 can have the same property as the first planarization layer 118, for example, a hydrophobic property.

Next, in FIGS. 6I and 7H, by depositing a conductive material on the second planarization layer 119 and then patterning it through a photolithography process, the second electrode 162 can be formed in the sub-pixel SP, and the third auxiliary pad 169 can be formed in the non-display area NDA. The second electrode 162 can also cover the light-emitting element 140 and be in contact with the second element electrode 142 of the light-emitting element 140. In addition, the second electrode 162 can be in contact with the second connection electrode 154 through the contact hole of the second planarization layer 119.

Further, the third auxiliary pad 169 can be formed inside the third dam 116c and can cover and contact the second auxiliary pad 159. As such, in the display device according to the first embodiment of the present disclosure, by providing the first, second, and third dams 116a, 116b, and 116c, the adhesive layer 117 and the first planarization layer 118 can be easily formed through an inkjet coating method.

Further, the first, second, and third dams 116a, 116b, and 116c can be formed as part of the overcoat layer 116, so that the number of processes is not increased. In addition, by forming the adhesive layer 117 only inside the first dam 116a, since a photolithography process for patterning the adhesive layer 117 can be omitted, it is possible to decrease the number of manufacturing processes compared to a display device in which an adhesive layer and a first planarization layer are formed all over a substrate.

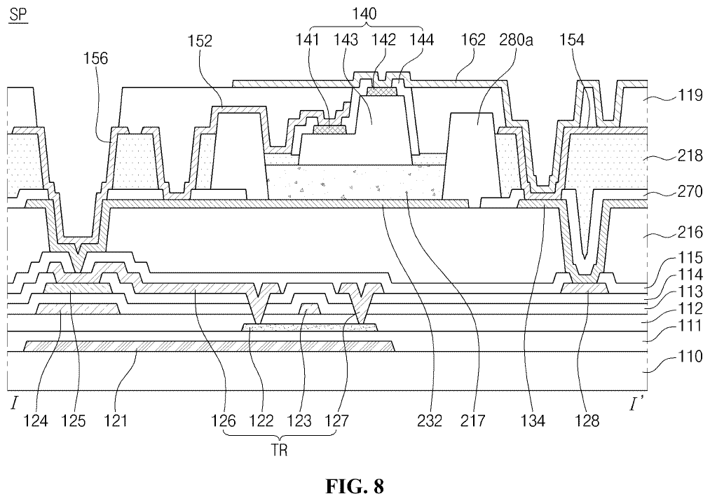

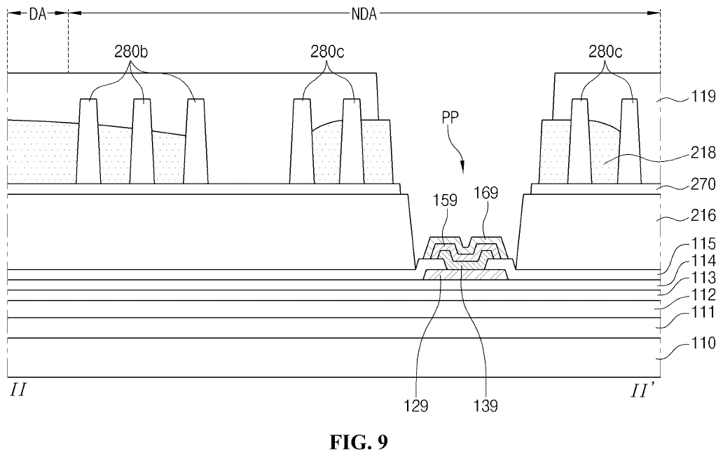

In addition, when the adhesive layer 117 and the first planarization layer 118 are formed using a material with a different property from the protection layer 144 of the light-emitting element 140, the ashing process can be omitted or minimized, so that the number and/or time of processes can be further decreased. Further, in the first embodiment, the first, second, and third dams 116a, 116b, and 116c can be formed as part of the overcoat layer 116. However, dams can be formed separately from the overcoat layer 116, and in this instance, the dams can be formed more reliably. Such a display device according to a second embodiment of the present disclosure will be described with reference to FIG. 8 and FIG. 9.

Next, FIG. 8 is a schematic cross-sectional view of a sub-pixel in a display area of a display device according to a second embodiment of the present disclosure and shows a cross-section corresponding to line I-I′ of FIG. 1, and FIG. 9 is a schematic cross-sectional view of a non-display area of the display device according to the second embodiment of the present disclosure and shows a cross-section corresponding to line II-II′ of FIG. 1. The display device according to the second embodiment of the present disclosure has substantially the same configuration as that of the first embodiment, except for an overcoat layer, an auxiliary passivation layer, and dams. The same parts as those of the first embodiment are designated by the same or similar reference signs, and explanation for the same parts can be shortened or omitted.

As shown in FIGS. 8 and 9, the display device according to the second embodiment of the present disclosure can include the substrate 110 provided with the display area DA and the non-display area NDA. Also, the sub-pixel SP can be provided in the display area DA, and the pad portion PP can be provided in the non-display area NDA. The thin film transistor TR, the light-emitting element 140, and the first dam 280a can also be provided in the sub-pixel SP of the display area DA, and the second dam 280b and the third dam 280c can be provided in the non-display area NDA.

Specifically, the thin film transistor TR can be provided in the sub-pixel SP on the substrate 110, the passivation layer 115 can be provided on the thin film transistor TR, and the overcoat layer 216 can be provided on the passivation layer 115. Further, the overcoat layer 216 can be disposed in both the display area DA and the non-display area NDA and can have a substantially flat top surface. In the non-display area NDA, the overcoat layer 216 can be removed to correspond to the pad portion PP.

In addition, the reflection electrode 232 and the first connection electrode 134 can be provided in the sub-pixel SP on the overcoat layer 216, and the first auxiliary pad 139 can be provided in the pad portion PP of the non-display area NDA. An auxiliary passivation layer 270 can also be provided on the reflection electrode 232 and the first connection electrode 134. The auxiliary passivation layer 270 can partially expose the reflection electrode 232 and the first connection electrode 134. In addition, the auxiliary passivation layer 270 can also be provided on the overcoat layer 216 in the non-display area NDA and can be removed to correspond to the pad portion PP.

Further, the auxiliary passivation layer 270 can be provided to effectively remove the first planarization layer 218. The auxiliary passivation layer 270 can also be removed. The first dam 280a, the second dam 280b, and the third dam 280c can be provided on the auxiliary passivation layer 270. Further, the first dam 280a can be disposed in the display area DA, and the second dam 280b and the third dam 280c can be disposed in the non-display area NDA.

In addition, the first dam 280a can correspond to the sub-pixel SP and can surround the light-emitting element 140. The first dam 280a can partially overlap the reflection electrode 232 and the auxiliary passivation layer 270, and the reflection electrode 232 can be exposed inside the first dam 280a. Also, the first dam 280a can be in contact with top and side surfaces of the auxiliary passivation layer 270 and can be in contact with top and side surfaces of the reflection electrode 232.

Further, the second dam 280b can be adjacent to the display area DA and can surround the display area DA. Also, the third dam 280c can be spaced apart from the second dam 280b and can surround the pad portion PP. In the sub-pixel SP, the adhesive layer 217 can be provided on the reflection electrode 232 inside the first dam 280a. The adhesive layer 217 can be disposed only inside the first dam 280a and not provided in the display area DA excluding the inside of the first dam 280a and the non-display area NDA. The adhesive layer 217 can have a hydrophobic property.

In the sub-pixel SP, the light-emitting element 140 can be provided on the adhesive layer 217. The light-emitting element 140 can also be disposed inside the first dam 280a and can be surrounded by the first dam 28a, and can overlap the reflection electrode 232. Further, the light-emitting element 140 can include the first element electrode 141, the second element electrode 142, the semiconductor layer 143, and the protection layer 144. Also, the protection layer 144 can have a hydrophilic property.

Next, the first planarization layer 218 can be provided on the adhesive layer 217 provided with the light-emitting element 140 thereon. For example, the first planarization layer 218 can be disposed substantially all over the display area DA and can be disposed both inside and outside the first dam 280a. In addition, the first planarization layer 218 can also be provided in the non-display area NDA. In the non-display area NDA, the first planarization layer 218 can be provided inside the second dam 280b and inside the third dam 280c and can be removed to correspond to the pad portion PP. Also, the first planarization layer 218 can have a hydrophobic property.

A height of the first planarization layer 218 can also be lower than heights of the first, second, and third dams 280a, 280b, and 280c to expose top surfaces of the first, second, and third dams 280a, 280b, and 280c. The first electrode 152, the second connection electrode 154, and the contact electrode 156 can be provided in the sub-pixel SP on the first planarization layer 218.

Further, the first electrode 152 can overlap the light-emitting element 140. The first electrode 152 can also be in contact with the first element electrode 141 of the light-emitting element 140 and be spaced apart from the second element electrode 142 of the light-emitting element 140. In addition, the first electrode 152 can be in contact with the reflection electrode 232 through a contact hole provided in the first planarization layer 218 and the auxiliary passivation layer 270. The first electrode 152 can also partially overlap the first dam 280a and be in contact with the top and side surfaces of the first dam 280a.

Also, the second connection electrode 154 can be in contact with the first connection electrode 134 through a contact hole provided in the first planarization layer 218 and the auxiliary passivation layer 270. In addition, the contact electrode 156 can be in contact with the reflection electrode 132 through a contact hole provided in the first planarization layer 218 and the auxiliary passivation layer 270.

Further, in the non-display area NDA, the second auxiliary pad 159 can be provided in the pad portion PP. For example, the second auxiliary pad 159 can be disposed in the hole of the overcoat layer 216 and can cover and contact the first auxiliary pad 139. Also, the second planarization layer 119 can be provided on the first electrode 152, the second connection electrode 154, and the contact electrode 156. The second planarization layer 119 can also be disposed in both the display area DA and the non-display area NDA.

The second planarization layer 119 can also cover the first element electrode 141 of the light-emitting element 140, the first electrode 152, and the first dam 280a and can partially expose the second element electrode 142 of the light-emitting element 140. In addition, the second planarization layer 119 can partially expose the second connection electrode 154 and the contact electrode 156.

In the non-display area NDA, the second planarization layer 119 can cover the first planarization layer 218, the second dam 280b, and the third dam 280c. The second planarization layer 119 can be removed to correspond to the pad portion PP. Further, the second planarization layer 119 can be removed between the second dam 280b and the third dam 280c or can be completely removed in the non-display area NDA.

Next, the second electrode 162 can be provided in the sub-pixel SP on the second planarization layer 119. In particular, the second electrode 162 can be in contact with the second element electrode 142 of the light-emitting element 140 and the second connection electrode 154. As such, in the display device according to the second embodiment of the present disclosure, by providing the first dam 280a, providing the adhesive layer 217 inside the first dam 280a, and transferring the light-emitting element 140 on the adhesive layer 217, the transfer location of the light-emitting element 140 can be specified, and the light-emitting element 140 can be easily transferred to a desired region. In addition, by forming the first, second, and third dams 280a, 280b, and 280c separately from the overcoat layer 216, the degree of freedom in process can be increased, and defects of the first, second, and third dams 280a, 280b, and 280c can be reduced.

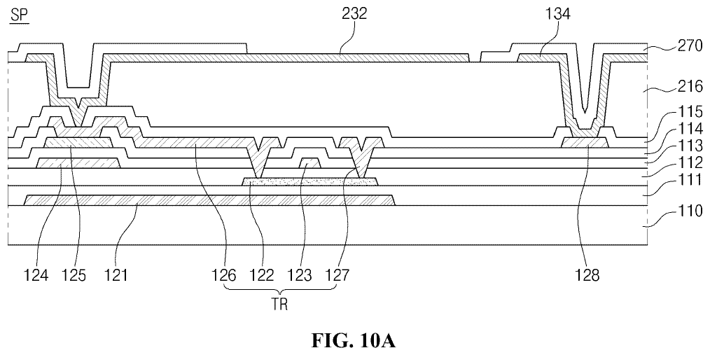

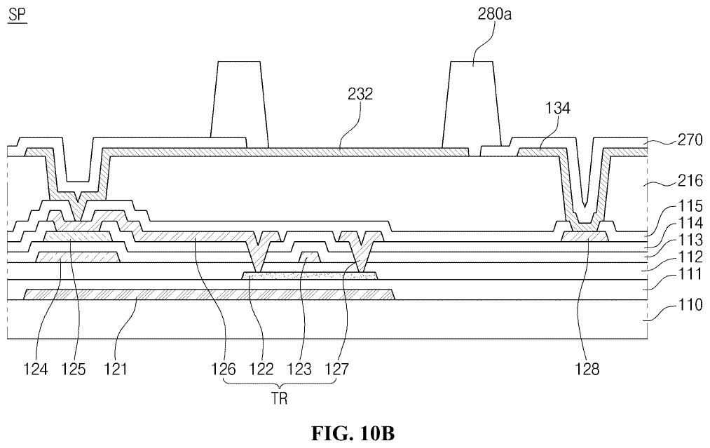

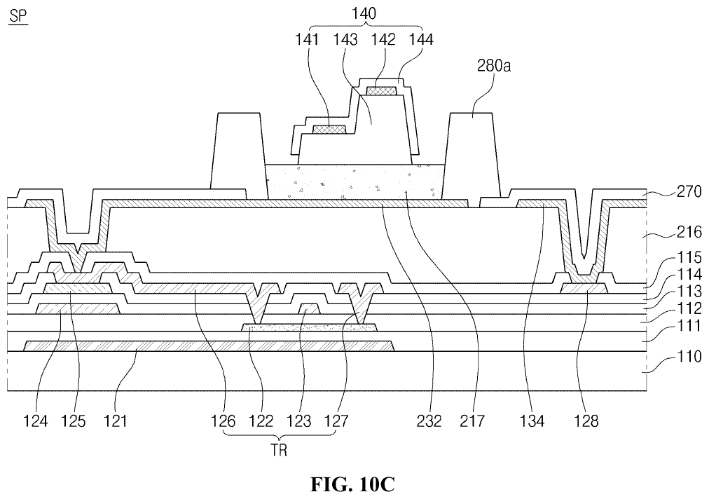

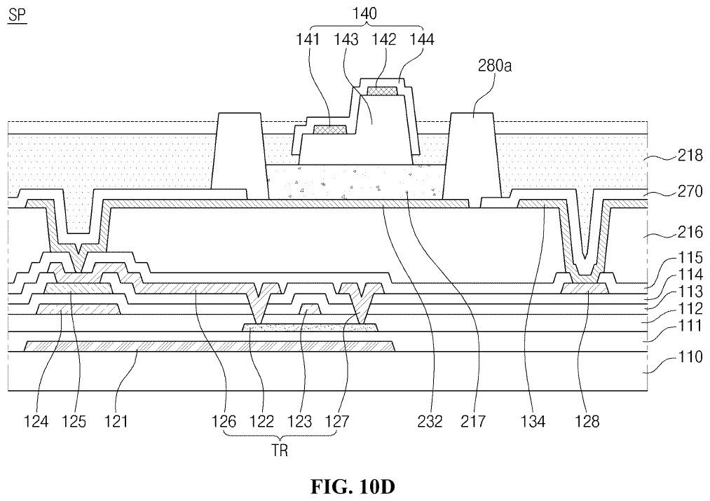

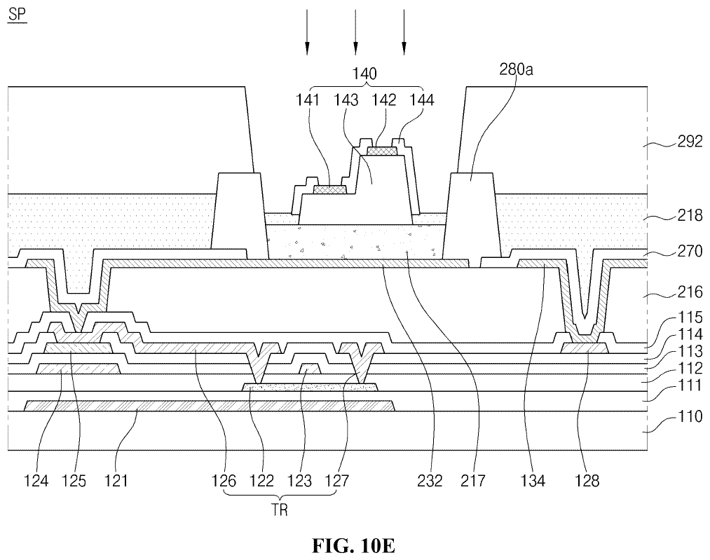

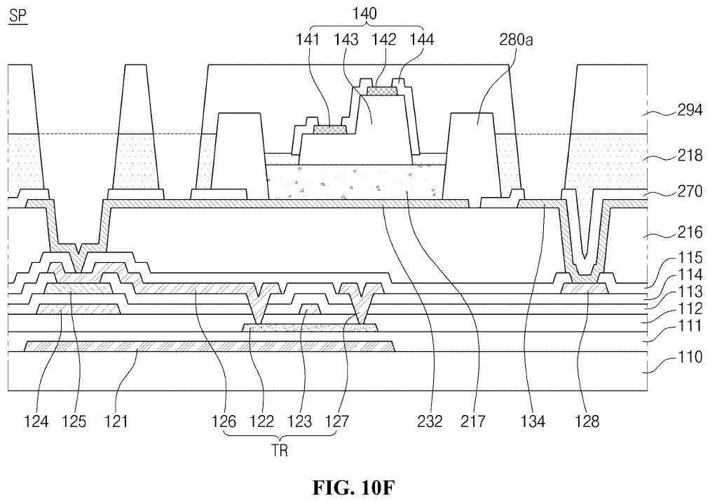

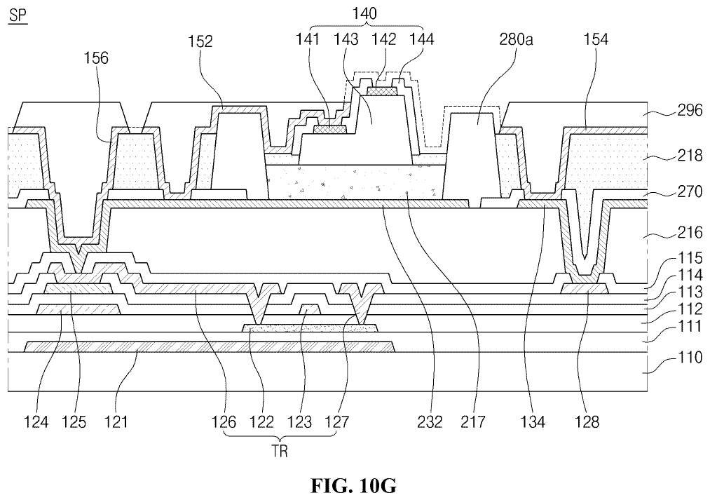

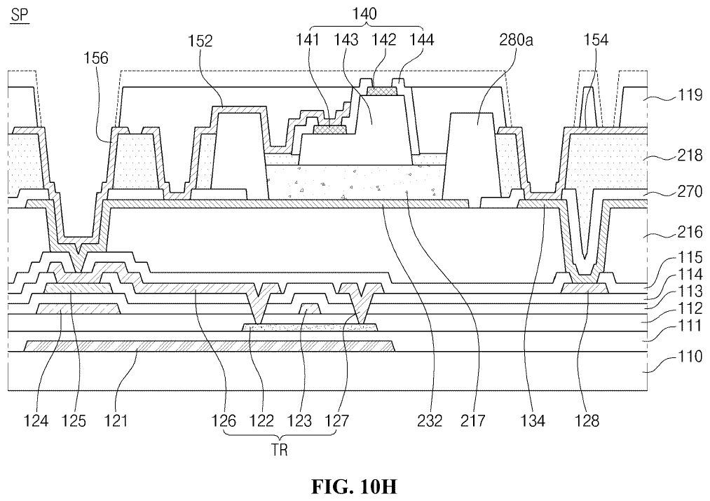

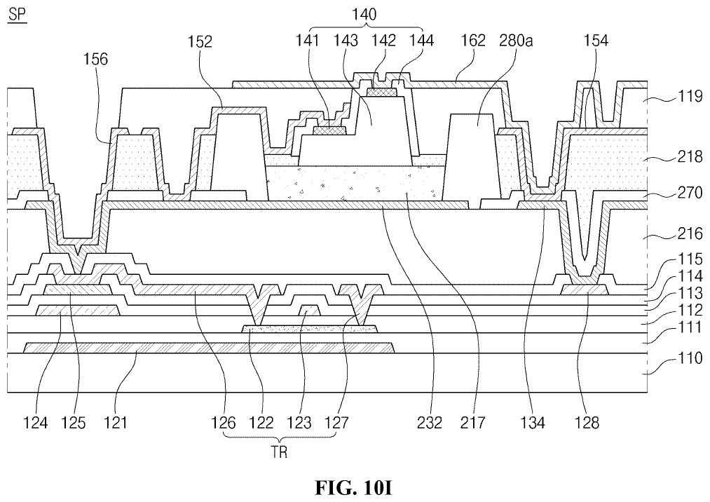

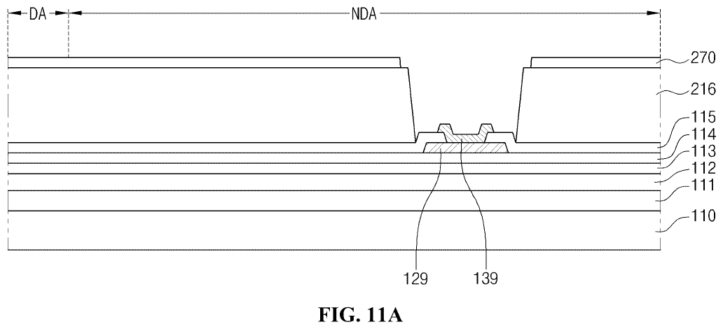

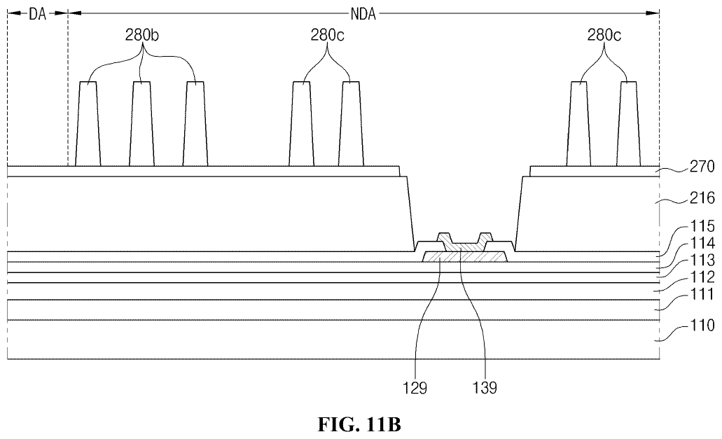

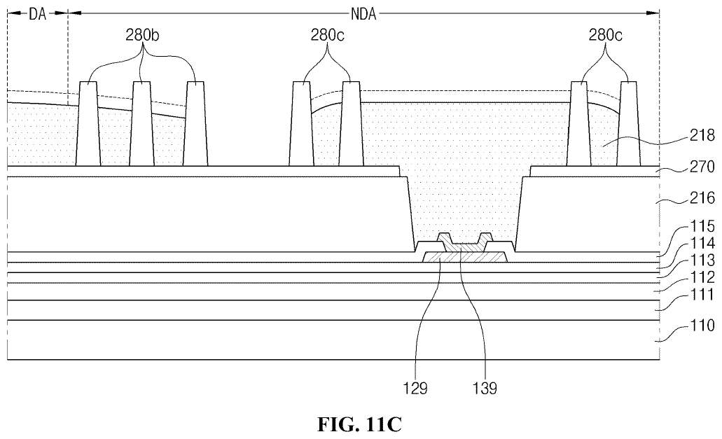

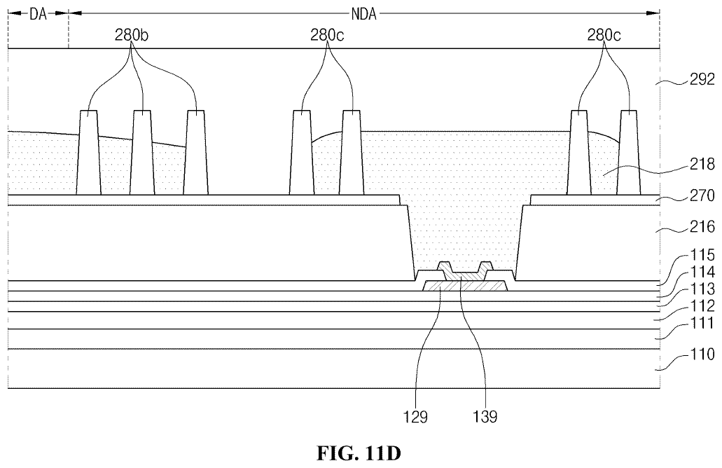

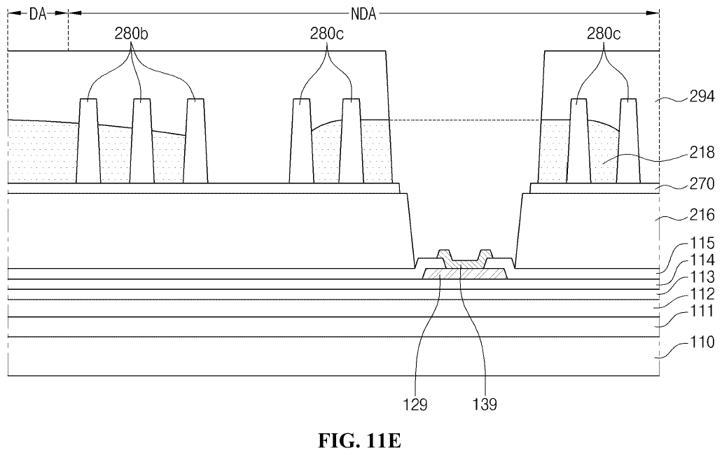

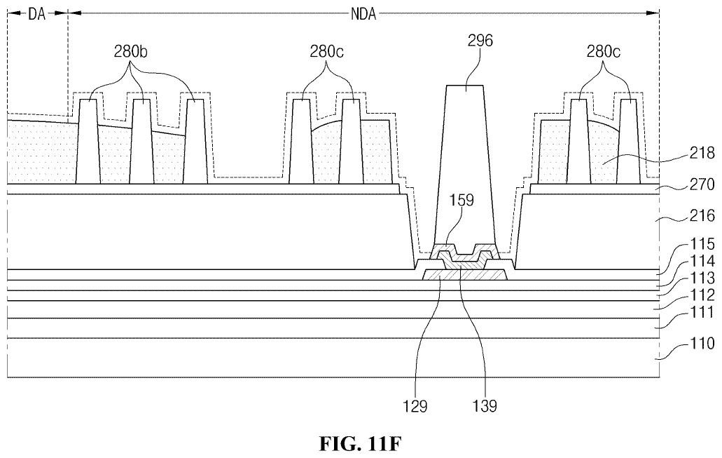

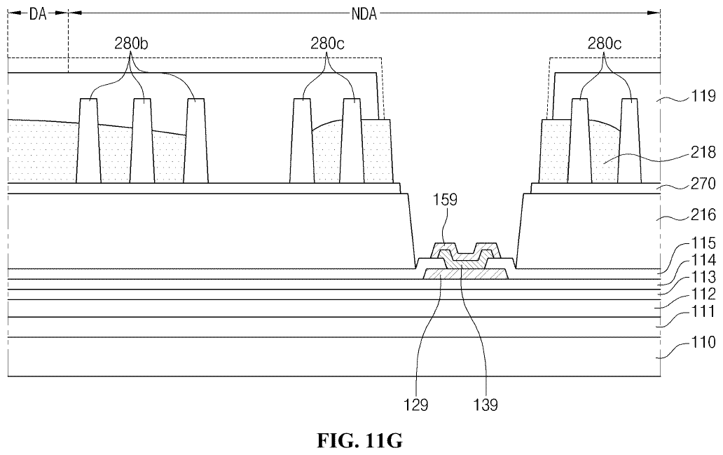

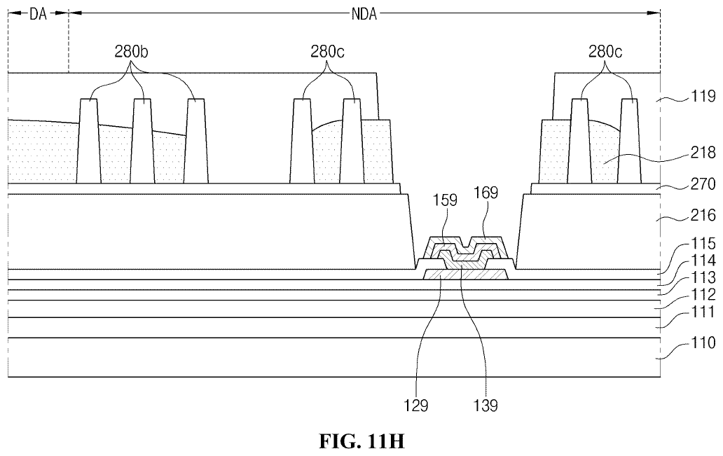

A method of manufacturing the display device according to the second embodiment of the present disclosure will be described with reference to FIGS. 10A to 10I and 11A to 11H. In particular, FIGS. 10A to 10I are schematic cross-sectional views of a display device in steps of manufacturing the same according to the second embodiment of the present disclosure and show cross-sections corresponding to line I-I′ of FIG. 1, and FIGS. 11A to 11H are schematic cross-sectional views of the display device in steps of manufacturing the same according to the second embodiment of the present disclosure and show cross-sections corresponding to line II-II′ of FIG. 1. The method of manufacturing the display device according to the second embodiment of the present disclosure includes substantially the same steps as those of the first embodiment, except for forming the overcoat layer, the auxiliary passivation layer, and the dam. The same parts as those of the first embodiment are designated by the same or similar reference signs, and explanation for the same parts can be shortened or omitted.

In FIGS. 10A and 11A, by repeating steps of depositing a thin film and selectively removing it through a photolithography process, the light-shielding layer 121, the buffer layer 111, the active layer 122, the gate insulation layer 112, the gate electrode 123 and the first capacitor electrode 124, the first interlayer insulation layer 113, the second capacitor electrode 125, the second interlayer insulation layer 114, the source and drain electrodes 126 and 127, the power line 128 and the pad electrode 129, and the passivation layer 115 can be sequentially formed on the substrate 110 provided with the display area DA and the non-display area NDA.

Next, the overcoat layer 216 can be formed on the passivation layer 115 by applying an organic insulating material, and the overcoat layer 216 and the passivation layer 115 thereunder can be selectively removed through a photolithography process, thereby forming the contact holes exposing the source electrode 126, the power line 128, and the pad electrode 129, respectively. Then, by depositing a conductive material on the overcoat layer 116 and then patterning it through a photolithography process, the reflection electrode 232 and the first connection electrode 134 can be formed in the sub-pixel SP, and the first auxiliary pad 139 can be formed in the non-display area NDA.

Next, the auxiliary passivation layer 270 can be formed on the reflection electrode 232, the first connection electrode 134, and the first auxiliary pad 139 by depositing an inorganic insulating material and patterning it through a photolithography process. The auxiliary passivation layer 270 can partially expose the reflection electrode 232.

Next, in FIGS. 10B and 11B, the first dam 280a, the second dam 280b, and the third dam 280c can be formed on the reflection electrode 232 and the auxiliary passivation layer 270 by applying an organic insulating material and patterning it through a photolithography process. Next, in FIG. 10C, the adhesive layer 217 can be formed on the reflection electrode 232 inside the first dam 280a by applying an adhesive material, and the light-emitting element 140 can be transferred on the adhesive layer 217. Also, the light-emitting element 140 can include the first element electrode 141, the second element electrode 142, the semiconductor layer 143, and the protection layer 144.

Next, in FIGS. 10D and 11C, the first planarization layer 218 can be formed over the substrate 110 on which the light-emitting element 140 is transferred by applying an organic insulating material. Also, the first planarization layer 218 can expose the protection layer 144 on the second element electrode 142. The first planarization layer 218 can be formed inside the second dam 280b including the first dam 280a and also be formed inside the third dam 280c. In addition, the first planarization layer 218 can be formed by an inkjet coating method.

Further, the protection layer 144 of the light-emitting element 140 can have a hydrophilic property, and the first planarization layer 218 and the adhesive layer 217 can have a hydrophobic property. Accordingly, the first planarization layer 218 can be formed relatively thinly or not formed on the protection layer 144 on the first element electrode 141 due to the different properties of the protection layer 144 and the first planarization layer 218. Also, the first planarization layer 218 can be stably formed on the adhesive layer 217 having the same property.

Then, the first planarization layer 218 can be partially removed from its top surface through an ashing process, thereby exposing the protection layer 144 on the first and second element electrodes 141 and 142 of the light-emitting element 140. In this instance, the top and side surfaces of the first, second, and third dams 280a, 280b, and 280c can also be partially exposed. Alternatively, if the first planarization layer 218 is not formed on the protection layer 144 on the first element electrode 141, the ashing process can be omitted.

Next, in FIGS. 10E and 11D, a first photoresist pattern 292 can be formed on the first planarization layer 218 through a photolithography process where photoresist is applied on the light-emitting element 140 and the first planarization layer 218, exposed to light, and developed. The first photoresist pattern 292 can expose the light-emitting element 140 inside the first dam 280a.

Then, the protection layer 144 of the light-emitting element 140 can be selectively removed, thereby exposing the first and second element electrodes 141 and 142. Here, the protection layer 144 can be removed through a dry etching process. In this instance, the first planarization layer 218 inside the first dam 280a can also be partially removed.

Next, in FIGS. 10F and 11E, the first photoresist pattern 292 can be stripped and removed, and a second photoresist pattern 294 can be formed on the light-emitting element 140 and the first planarization layer 218 through a photolithography process where photoresist is applied, exposed to light, and developed. Then, the first planarization layer 218 can be selectively removed using the second photoresist pattern 294 as an etching mask, thereby partially exposing the reflection electrode 232 and the first connection electrode 134 and completely exposing the first auxiliary pad 139.

Next, in FIGS. 10G and 11F, the second photoresist pattern 294 can be stripped and removed, and a conductive material layer can be formed substantially all over the substrate 110 by depositing a conductive material on the light-emitting element 140 and the first planarization layer 218. Then, a third photoresist pattern 296 can be formed on the conductive material layer through a photolithography process where photoresist is applied, exposed to light, and developed.

Next, by selectively removing the conductive material layer using the third photoresist pattern 296 as an etching mask, the first electrode 152, the second connection electrode 154, and the contact electrode 156 can be formed in the sub-pixel SP, and the second auxiliary pad 159 can be formed in the non-display area NDA.

Next, in FIGS. 10H and 11G, the third photoresist pattern 296 can be stripped and removed. Further, the second planarization layer 119 can be formed on the first electrode 152, the second connection electrode 154, the contact electrode 156, and the second auxiliary pad 159 by applying an organic insulating material and then patterned through a photolithography process, thereby exposing the second connection electrode 154 and the contact electrode 156. In addition, the second planarization layer 119 can cover the second dam 280b and the third dam 280c in the non-display area NDA and can be removed inside the third dam 280c, thereby exposing the second auxiliary pad 159. Then, the second planarization layer 119 can be partially removed through an ashing process, thereby exposing the second element electrode 142 of the light-emitting element 140.

Next, in FIGS. 10I and 11H, by depositing a conductive material on the second planarization layer 119 and then patterning it through a photolithography process, the second electrode 162 can be formed in the sub-pixel SP, and the third auxiliary pad 169 can be formed in the non-display area NDA. In addition, the second electrode 162 can be in contact with the second element electrode 142 of the light-emitting element 140 and can also be in contact with the second connection electrode 154 through the contact hole of the second planarization layer 119. Further, the third auxiliary pad 169 can cover and contact the second auxiliary pad 159.

As such, in the display device according to the second embodiment of the present disclosure, by providing the first, second, and third dams 280a, 280b, and 280c, the adhesive layer 217 and the first planarization layer 218 can be easily formed through an inkjet coating method. Since the first, second, and third dams 280a, 280b, and 280c are separately formed through a different process from the overcoat layer 216, the degree of freedom in process can be increased, and defects of the first, second, and third dams 280a, 280b, and 280c can be reduced.

In the display device of the present disclosure, by providing the dams for formation of the adhesive layer and the first planarization layer, the light-emitting element can be easily transferred to a desired region. The dams can be formed as part of the overcoat layer, and the photolithography process for patterning the adhesive can be omitted, so that the number of manufacturing processes can be reduced. Alternatively, by forming the dams through a different process from the overcoat layer, the degree of freedom in process can be increased, and defects of the dams can be reduced.

In addition, by forming the first planarization layer using a material with a different property from the light-emitting element, the ashing process can be omitted or minimized, so that the number and/or time of processes can be further decreased. Accordingly, the manufacturing process of the display device can be optimized and the production energy can be reduced.

It will be apparent to those skilled in the art that various modifications and variations can be made in the display device and the method of manufacturing the same of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device, comprising:
a substrate having a display area and a non-display area;
a thin film transistor in the display area over the substrate;
a first dam at least partially overlapping the thin film transistor;
an adhesive layer inside the first dam;
a light-emitting element provided on the adhesive layer and including a semiconductor layer, a first element electrode on the semiconductor layer, a second element electrode on the semiconductor layer and disposed higher than the first element electrode, and a protection layer on the first element electrode, the second element electrode, and the semiconductor layer and including a first opening partially exposing a top surface of the first element electrode and a second opening partially exposing a top surface of the second element electrode; and
a planarization layer provided over the adhesive layer and surrounding a side surface of the light-emitting element and a side surface of the protection layer,
wherein the planarization layer has a hydrophobic property and the protection layer has a hydrophilic property, and
wherein the first dam surrounds the light-emitting element with a height of the first element electrode being disposed lower than a height of the first dam, and a height of the second element electrode being disposed higher than the height of the first dam.

2. The display device of claim 1, wherein a height of the planarization layer within inner surfaces of the first dam is lower than the height of the first dam.

3. The display device of claim 1, wherein the adhesive layer has a hydrophobic property.

4. The display device of claim 1, further comprising:
an overcoat layer between the thin film transistor and the adhesive layer,
wherein the overcoat layer includes the first dam.

5. The display device of claim 4, further comprising:
a reflection electrode between the overcoat layer and the adhesive layer,
wherein the reflection electrode extends along inner side surfaces of the first dam.

6. The display device of claim 1, further comprising:
an overcoat layer between the thin film transistor and the adhesive layer,
wherein the first dam is disposed between the overcoat layer and the planarization layer.

7. The display device of claim 6, further comprising:
a reflection electrode between the overcoat layer and the adhesive layer,
wherein the reflection electrode is disposed between the overcoat layer and the first dam.

8. The display device of claim 1, further comprising:
a second dam in the non-display area over the substrate and surrounding the display area.

9. The display device of claim 8, further comprising:
a pad portion in the non-display area over the substrate; and
a third dam surrounding the pad portion.

10. The display device of claim 9, wherein the planarization layer is provided inside the second dam and inside the third dam and is not provided between the second dam and the third dam.

11. The display device of claim 9, wherein the second dam and the third dam have a height set to block the planarization layer from being between the second dam and the third dam.

12. The display device of claim 1, further comprising:
a first electrode provided over the planarization layer and electrically connected to the first element electrode; and
a second electrode provided over the first electrode and electrically connected to the second element electrode.

13. A method of manufacturing a display device, the method comprising:
forming a thin film transistor in a display area of a substrate;
forming a first dam at least partially overlapping the thin film transistor;
forming an adhesive layer inside the first dam;
transferring a light-emitting element onto the adhesive layer, the light-emitting element including a semiconductor layer, a first element electrode on the semiconductor layer, a second element electrode on the semiconductor layer and disposed higher than the first element electrode, and a protection layer on the first element electrode, the second element electrode, and the semiconductor layer and including a first opening partially exposing a top surface of the first element electrode and a second opening partially exposing a top surface of the second element electrode; and
forming a planarization layer over the adhesive layer, the planarization layer surrounding a side surface of the light-emitting element and a side surface of the protection layer,
wherein the planarization layer has a hydrophobic property and the protection layer has a hydrophilic property, and
wherein the first dam surrounds the light-emitting element with a height of the first element electrode being disposed lower than a height of the first dam, and a height of the second element electrode being disposed higher than the height of the first dam.

14. The method of claim 13, wherein the adhesive layer and the planarization layer are formed by an inkjet coating method.

15. The method of claim 14, wherein forming the first dam includes forming a second dam in the non-display area over the substrate, and the second dam surrounds the display area.

16. The method of claim 13, further comprising:
forming an overcoat layer between forming the thin film transistor and forming the adhesive layer,
wherein forming the first dam is performed through a same process as forming the overcoat layer.

17. The method of claim 13, further comprising:
forming an overcoat layer between forming the thin film transistor and forming the adhesive layer,
wherein forming the first dam is performed between forming the overcoat layer and forming the adhesive layer.

18. The method of claim 13, wherein a height of the planarization layer within inner surfaces of the first dam is lower than the height of the first dam.

19. The method of claim 13, wherein the adhesive layer has a hydrophobic property.

20. The method of claim 13, wherein the second dam and the third dam have a height set to block the planarization layer from being between the second dam and the third dam.
